(19) United States
(12) Patent Application Publication
(10) Pub. No.: US 2026/0068550 A1
(43) Pub. Date: Mar. 5, 2026

(54) PULSE ETCHING FOR FINFET AND GAA SOURCE/DRAIN EPI FILM GROWTH CONTROL

(71) Applicant: Applied Materials, Inc., Santa Clara, CA (US)

(72) Inventors: Xuebin LI, Sunnyvale, CA (US); John TOLLE, Gilbert, AZ (US); Zhepeng CONG, San Jose, CA (US)

(21) Appl. No.: 19/317,218

(22) Filed: Sep. 3, 2025

Related U.S. Application Data
(60) Provisional application No. 63/690,248, filed on Sep. 3, 2024.

(51) Int. Cl. H01L 21/02; C30B 33/12; H01L 21/3065; H10D 62/00

(52) U.S. Cl. CPC H01L 21/0262; C30B 33/12; H10D 62/021

(57) ABSTRACT

Methods and systems for fabricating semiconductor devices that use a cyclic pulse-etch-purge process, particularly after epitaxial film deposition, are provided. The process involves alternating flows of etch and purge gases (such as H2, N2, HCl, Cl2, and others) and optionally deposition gases to selectively remove unwanted doped silicon-containing material, shaping epitaxial features with precise profiles and minimizing defects like voids. The method can be performed in-situ in the same chamber as deposition and uses controlled cycles of gas pulses to achieve targeted source/drain feature formation. It supports various process parameters and chemistries, is compatible with standard nMOS and pMOS conditions, and can be implemented in automated semiconductor manufacturing environments.

### CROSS REFERENCE TO RELATED APPLICATIONS

This application claims the benefit of U.S. Provisional Patent Application Ser. No. 63/690,248, filed Sep. 3, 2024, which is incorporated by reference herein in its entirety.

### TECHNICAL FIELD

The present disclosure relates to advanced transistor devices and methods for manufacturing advanced transistor devices. More particularly, the present disclosure relates to multi-gate devices including gate-all around (GAA) transistor devices and Fin Field-Effect Transistors (FinFET) devices and methods for manufacturing the same.

### BACKGROUND

The electronics industry is experiencing an ever-increasing demand for smaller and faster electronic devices which are simultaneously able to support a greater number of increasingly complex and sophisticated functions. Accordingly, there is a continuing trend in the semiconductor industry to manufacture low-cost, high-performance, and low-power integrated circuits (ICs). So far, these goals have been achieved in large part by scaling down semiconductor IC dimensions (e.g., minimum feature size) and thus improving production efficiency and lowering associated costs. However, such miniaturization has introduced greater complexity into the semiconductor manufacturing process. Thus, the realization of continued advances in semiconductor ICs and devices calls for similar advances in semiconductor manufacturing processes and technology.

Recently, multi-gate devices have been introduced to improve gate control by increasing gate-channel coupling, reducing OFF-state current, and reducing short-channel effects (SCEs). One such multi-gate device that has been introduced is a Fin Field-Effect Transistors (FinFET) device. In a FinFET device a fin-shaped channel sits above the substrate, and the gate wraps around three sides of the fin. The gate controls the flow of current through the fin, offering improved control relative to planar transistors. Another multi-gate device that has been introduced is the gate-all around transistor (GAA). In a GAA device all side surfaces of the channel region are surrounded by the gate electrode, which allows for fuller depletion in the channel region and results in less short-channel effects due to a steeper sub-threshold current swing and smaller drain induced barrier lowering (DIBL).

As transistor dimensions are scaled down to smaller technology nodes, there is a need for further improvements in multi-gate device design and manufacturing.

### SUMMARY

The present disclosure relates to advanced transistor devices and methods for manufacturing advanced transistor devices. More particularly, the present disclosure relates to multi-gate devices including gate-all around (GAA) transistor devices and Fin Field-Effect Transistors (FinFET) devices and methods for manufacturing the same.

In one aspect, a processing system is provided. The processing system includes one or more processing chambers and a system controller. The system controller is configured to cause the processing system to perform (a) a pre-clean process on exposed surfaces of a semiconductor structure, the semiconductor structure comprising a first semiconductor region, a second semiconductor region separated from the first semiconductor region by a trench, and a dielectric layer over at least a portion of the first semiconductor region and the second semiconductor region; (b) a first epitaxial deposition process to form a doped silicon-containing layer on the exposed surfaces of the semiconductor structure; and c) a pulse-etch-purge process to remove portions of the doped silicon-containing layer from the sidewall surfaces of the trench.

In another aspect, a method of forming a semiconductor device is provided. The method includes performing an epitaxial deposition process. The epitaxial deposition process includes epitaxially growing a doped silicon-containing material on a pair of opposing sidewall surfaces and a bottom surface to a targeted thickness. The pair of opposing sidewall surfaces and the bottom surface defining a source/drain cavity. The method further includes performing a cyclic pulse-etch-purge process for a number of cycles to selectively remove portions of the doped silicon-containing material from the sidewall surfaces to form a modified doped silicon-containing material. The modified doped silicon-containing material has a U-shaped profile.

Implementations of the aforementioned aspects may include one or more of the following. The epitaxial deposition process and the cyclic pulse-etch-purge process are repeated for a number of cycles to fill the source/drain cavity to a targeted thickness with the doped silicon-containing material. The pulse-etch-purge process removes an upper portion of the doped silicon-containing material coating an upper portion of the sidewall surfaces at greater rate than a lower portion of the doped silicon-containing material coating a lower portion of the sidewall surfaces and the bottom surface. The cyclic pulse-etch-purge process further includes pulsing a silicon deposition gas, a germanium deposition gas, or both a silicon deposition gas and a germanium deposition gas. The cyclic pulse-etch-purge process includes pulsing an etchant gas selected from HCl, Cl2, HBr, PCl3, AsCl3, GeCl4, or a combination thereof. The cyclic pulse-etch-purge process further includes pulsing a carrier gas selected from hydrogen, nitrogen, or a combination thereof. The cyclic pulse-etch-purge process further includes pulsing a silicon deposition gas, a germanium deposition gas, or both a silicon deposition gas and a germanium deposition gas.

In yet another aspect, a method of forming a semiconductor device is provided. The method includes performing an epitaxial deposition process in a processing volume of a processing chamber. The epitaxial deposition process includes epitaxially growing a doped silicon-containing material on a pair of opposing sidewall surfaces and a bottom surface to a targeted thickness. The pair of opposing sidewall surfaces and the bottom surface defining a source/drain cavity. The method further includes performing a cyclic pulse-etch-purge process subsequent to the epitaxial deposition process. The cyclic pulse-etch-purge process includes pulsing a process gas including an etchant gas into the processing volume for a first period of time, pulsing a purge gas into the processing volume for a second period of time, and repeating the cyclic pulse-etch-purge process for a number of cycles to selectively remove a portion of the doped silicon-containing material from the sidewall surfaces of the source/drain cavity.

Implementations of the aforementioned aspects may include one or more of the following. The epitaxial deposition process and the cyclic pulse-etch-purge process are repeated for a number of cycles to fill the source/drain cavity to a targeted thickness with the doped silicon-containing material. The first period of time is less than the second period of time. The second period of time is five seconds or less. The etchant gas and the purge gas are laterally injected into the processing volume. The etchant gas and the purge gas are vertically injected into the processing volume. The etchant gas is HCl, Cl2, HBr, PCl3, AsCl3, GeCl4, or a combination thereof. The process gas further includes a silicon deposition gas, a germanium deposition gas, or both a silicon deposition gas and a germanium deposition gas. The cyclic pulse-etch-purge process further includes pulsing a silicon deposition gas, a germanium deposition gas, or both a silicon deposition gas and a germanium deposition gas.

In yet another aspect, a non-transitory computer readable medium includes instructions that, when executed, cause a plurality of operations to be conducted, the plurality of operations, including performing an epitaxial deposition process in a processing volume of a processing chamber. The epitaxial deposition process includes epitaxially growing a doped silicon-containing material on a pair of opposing sidewall surfaces and a bottom surface to a targeted thickness. The pair of opposing sidewall surfaces and the bottom surface defining a source/drain cavity. The method further includes performing a cyclic pulse-etch-purge process subsequent to the epitaxial deposition process. The cyclic pulse-etch-purge process, including pulsing a process gas including an etchant gas into the processing volume for a first period of time, pulsing a purge gas into the processing volume for a second period of time, and repeating the cyclic pulse-etch-purge process for a number of cycles to selectively remove a portion of the doped silicon-containing material from the sidewall surfaces of the source/drain cavity.

Implementations of the aforementioned aspects may include one or more of the following. The epitaxial deposition process and the cyclic pulse-etch-purge process are repeated for a number of cycles to fill the source/drain cavity to a targeted thickness with the doped silicon-containing material. The first period of time is less than the second period of time. The second period of time is five seconds or less. The etchant gas and the purge gas are laterally injected into the processing volume. The etchant gas and the purge gas are vertically injected into the processing volume. The etchant gas is HCl, Cl2, HBr, PCl3, AsCl3, GeCl4, or a combination thereof. The process gas further includes a silicon deposition gas, a germanium deposition gas, or both a silicon deposition gas and a germanium deposition gas. The cyclic pulse-etch-purge process further includes pulsing a silicon deposition gas, a germanium deposition gas, or both a silicon deposition gas and a germanium deposition gas.

In yet another aspect, a non-transitory computer readable medium has stored thereon instructions, which, when executed by a processor, causes the process to perform operations of the above apparatus and/or method.

### BRIEF DESCRIPTION OF THE DRAWINGS

So that the manner in which the above-recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of scope, and may admit to other equally effective embodiments.

FIG. 1 is a schematic top view of a multi-chamber processing system in accordance with one or more embodiments of the present disclosure.

FIG. 2 is a cross-sectional view of a processing chamber in accordance with one or more embodiments of the present disclosure.

FIG. 3 illustrates an exemplary flow chart of a method in accordance with one or more embodiments of the present disclosure.

FIGS. 4A-4D illustrate side views of various stages of manufacturing a semiconductor device structure according to the method of FIG. 3 in accordance with one or more embodiments of the present disclosure.

FIG. 5 illustrates an exemplary flow chart of another method in accordance with one or more embodiments of the present disclosure.

FIGS. 6A-6B illustrate side views of various stages of manufacturing a semiconductor device structure according to the method of FIG. 5 in accordance with one or more embodiments of the present disclosure.

FIG. 7 illustrates an exemplary flow chart of yet another method in accordance with one or more embodiments of the present disclosure.

FIGS. 8A-8D illustrate side views of various stages of manufacturing a semiconductor device structure according to the method of FIG. 7 in accordance with one or more embodiments of the present disclosure.

FIG. 9 illustrates an exemplary flow chart of yet another method in accordance with one or more embodiments of the present disclosure.

To facilitate understanding, identical reference numerals have been used, where possible, to designate identical elements that are common to the figures. It is contemplated that elements and features of one implementation may be beneficially incorporated in other embodiments without further recitation.

### DETAILED DESCRIPTION

The present disclosure relates to advanced transistor devices and methods for manufacturing advanced transistor devices. More particularly, the present disclosure relates to multi-gate devices including gate-all around (GAA) transistor devices and Fin Field-Effect Transistors (FinFET) devices and methods for manufacturing the same.

Scaling down of silicon metal oxide semiconductor (MOS) devices has become a major challenge in the semiconductor industry. One problem with the scaling of conventional planar devices is the short channel effects, which start to dominate over device performance. One solution to this problem came with the introduction of multi-gate devices with three-dimensional architecture, such as fin-based semiconductor devices or FinFETs and GAA devices. Due to their three-dimensional architecture with either the gate being wrapped around a thin semiconductor fin for FinFET or the gate electrode surrounding all side surfaces of the channel region for GAA, improved gate control (and thus less short channel effects) over the channel could be achieved by using multiple gates.

Epitaxial film growth on multi-gate devices typically suffers from several deficiencies. For example, during epitaxial film growth for source/drain (S/D) features on GAA structures, the epitaxial film easily forms thicker film on the top silicon pair, causing the top silicon pair to merge early (called pinch-off; or over-bridging) leaving hidden voids within the S/D recess film. In addition, strong lateral epitaxial growth along the sidewall surfaces can lead to merging and defective epitaxial film growth (or unfilled seam/gap) within the film. This undesirable merging can adversely affect local critical dimension uniformity (LCDU). Some embodiments of the present disclosure provide epitaxial growth shape/defectivity control including: (1) bottom-up growth (instead of strong sidewall growth); (2) thinning of the epitaxial structure on the top silicon pair by a cyclic pulse etching process to suppress top-pair “pinch-off” (void issue); and/or (3) shaping of the epitaxial structure to reduce or prevent merging between adjacent nMOS structures, adjacent pMOS structure, and/or adjacent pMOS and nMOS structures.

Embodiments of the present disclosure proved a pulsed etching approach. After deposition of a targeted Epi film thickness, etchant gas can be injected into an epitaxial chamber for a short time period (˜seconds) before purging the etchant gas out of chamber. In this cyclic pulse etching mode, etchant gas molecules do not have sufficient time to reach the bottom of the trench in the GAA or FinFET by collision. Accordingly, the top portion of the GAA or FinFET recess can be gently etched away by the incoming etchant gas. It can be imagined as “gas supply depletion” in a transit from top structure to bottom structure to preferentially etch films on the sidewall and top portion of the GAA or FinFET. After multiple cycles of “pulse-etch-purge,” a thinner epitaxial film is present at the top of the recess without void issues, and a V-shaped or U-shaped film profile is present. The V-shaped or U-shaped film profile favors “bottom-up” growth within the trench of the GAA or FinFET.

The “pulse-etch-purge” process is applicable to both NMOS and PMOS structures. As an example, the methods can form film as part of n-type epitaxial deposition such as to form silicon phosphorus (Si:P) for NMOS (N-channel MOSFET) transistors. As an example, the methods can form film as part of p-type epitaxial deposition such as to form silicon-germanium-boron (SiGe:B) for PMOS (P-channel MOSFET) transistors.

In one or more embodiments, the cyclic pulse etching process includes epitaxial partial fill deposition followed by multiple cycles of “pulse-etch-purge” followed by epitaxial partial fill deposition followed by multiple cycles of “pulse etch-purge” until the GAA or FinFET recess is filled to a targeted thickness. The cyclic pulse etching process described can be performed using typical NMOS and PMOS process conditions. The pulse etch time can be less than the purge etch time. The temperature during the cyclic pulse etching process could be either the same or different from the epitaxial deposition temperature. Pulse etch pressure/purge pressure can be in a range from about 5 torr to about 600 torr. The pulse etchant gases can be provided in a carrier gas, for example, H2 or N2, at a flow rate in a range from about 500 sccm to 30 SLM. The carrier gas can be used as the purge gas during the purge operation. Etchant gases include but are not limited to (1) HCl, Cl2, HBr, and other suitable etchants compatible in the chamber design; (2) PCl3, AsCl3, GeCl4 as both etchant gas and P, As, and Ge source gases; (3) 1 or 2, with the additional Si and Ge source gases (SiH4, SiH2Cl2, Si2H6, Si3H8, Si4H10, GeH4, Ge2H6, etc.); and (4) 1, 2, 3 types of gases can be injected (in the pulse mode) at the same time or in any sequential order. In one or more embodiments, sequential order includes injecting deposition gas and etchant gases at different time slots in a pulsed way similar to an atomic layer deposition process. The pulsed etchant and purge gases can be laterally injected into the processing volume and purged out of the processing volume on the exhaust side. The pulsed etchant and purge gases can be vertically injected into the processing volume through the XT plate with (mesh holes), for example, a showerhead.

In one or more other embodiments, the cyclic pulse etching process includes epitaxial full fill deposition followed by multiple cycles of pulse etching to reopen the epitaxial structure and remove voids followed by additional epitaxial deposition followed by multiple cycles of pulse etching until the GAA or FinFET recess is filled to a targeted thickness.

In one or more other embodiments, an epitaxial deposition process followed by a cyclic etching process is provided. The epitaxial deposition process deposits an epitaxial film to a targeted thickness followed by multiple cycles of the cyclic etching process to remove portions of the epitaxial structure.

In one or more embodiments, a cyclic pulse deposition/pulse etch process is provided. In one or more embodiments, one cycle of the cyclic pulse deposition/pulse etch process includes a pulse of deposition gas followed by of pulse of etching gas. The cyclic pulse deposition/pulse etch process can be repeated for a number of cycles to deposit an epitaxial material, for example, a silicon-containing epitaxial material, a germanium-containing epitaxial material, or a silicon and germanium-containing material. The cyclic pulse deposition/pulse etch process can further include a pulse of purge gas between the pulse of deposition gas and the pulse of etching gas. For example, one cycle of the cyclic pulse deposition/pulse etch process can include a pulse of deposition gas followed by a pulse of purge gas followed by a pulse of etching gas. In some embodiments which exclude the purge gas, the etch gas and deposition gas can mix in a dynamic way, for example, the gas mixture can be rich in deposition gas or rich in etching gas. In some embodiments which include the purge gas, the purge gas reduces interaction of the deposition gas and the etching gas in the chamber.

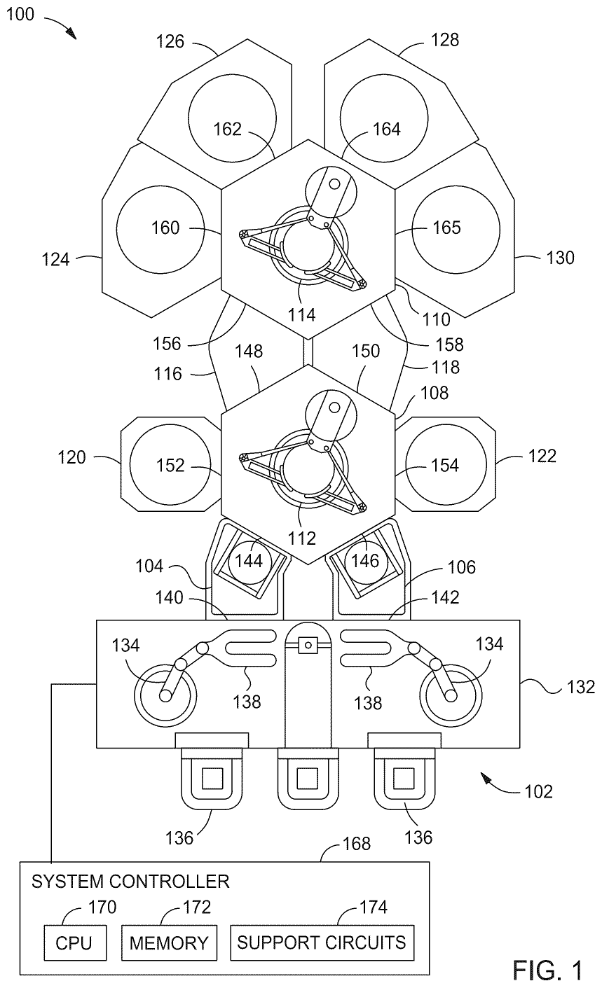

FIG. 1 is a schematic top view of a multi-chamber processing system 100, according to one or more embodiments of the present disclosure. The multi-chamber processing system 100 generally includes a factory interface 102, load lock chambers 104, 106, transfer chambers 108, 110 with respective transfer robots 112, 114, holding chambers 116, 118, and processing chambers 120, 122, 124, 126, 128, 130. As detailed herein, substrates in the multi-chamber processing system 100 can be processed in and transferred between the various chambers without exposing the substrates to an ambient environment exterior to the multi-chamber processing system 100 (e.g., an atmospheric ambient environment such as may be present in a fab). For example, the substrates can be processed in and transferred between the various chambers maintained at a low pressure (e.g., less than or equal to about 300 Torr) or vacuum environment without breaking the low pressure or vacuum environment among various processes performed on the substrates in the multi-chamber processing system 100. Accordingly, the multi-chamber processing system 100 may provide an integrated solution for some processing of substrates.

Examples of a processing system that may be suitably modified in accordance with the teachings provided herein include the Endura®, Producer® or Centura® integrated processing systems or other suitable processing systems commercially available from Applied Materials, Inc., located in Santa Clara, California. It is contemplated that other processing systems (including those from other manufacturers) may be adapted to benefit from aspects described herein.

In the illustrated example of FIG. 1, the factory interface 102 includes a docking station 132 and factory interface robots 134 to facilitate transfer of substrates. The docking station 132 is adapted to accept one or more front opening unified pods (FOUPs) 136. In some examples, each factory interface robot 134 generally includes a blade 138 disposed on one end of the respective factory interface robot 134 adapted to transfer the substrates from the factory interface 102 to the load lock chambers 104, 106.

The load lock chambers 104, 106 have respective ports 140, 142 coupled to the factory interface 102 and respective ports 144, 146 coupled to the transfer chamber 108. The transfer chamber 108 further has respective ports 148, 150 coupled to the holding chambers 116, 118 and respective ports 152, 154 coupled to processing chambers 120, 122. Similarly, the transfer chamber 110 has respective ports 156, 158 coupled to the holding chambers 116, 118 and respective ports 160, 162, 164, 165 coupled to processing chambers 124, 126, 128, 130. The ports 144, 146, 148, 150, 152, 154, 156, 158, 160, 162, 164, 165 can be, for example, slit valve openings with slit valves for passing substrates therethrough by the transfer robots 112, 114 and for providing a seal between respective chambers to prevent a gas from passing between the respective chambers. Generally, any port is open for transferring a substrate therethrough. Otherwise, the port can be closed.

The load lock chambers 104, 106, transfer chambers 108, 110, holding chambers 116, 118, and processing chambers 120, 122, 124, 126, 128, 130 may be fluidly coupled to a gas and pressure control system. The gas and pressure control system can include one or more gas pumps (e.g., turbo pumps, cryo-pumps, roughing pumps), gas sources, various valves, and conduits fluidly coupled to the various chambers. In operation, a factory interface robot 134 transfers a substrate from a FOUP 136 through a port 140 or 142 to a load lock chamber 104 or 106. The gas and pressure control system then pumps down the load lock chamber 104 or 106. The gas and pressure control system further maintains the transfer chambers 108, 110 and holding chambers 116, 118 with an interior low pressure or vacuum environment (which may include an inert gas). Hence, the pumping down of the load lock chamber 104 or 106 facilitates passing the substrate between, for example, the atmospheric environment of the factory interface 102 and the low pressure or vacuum environment of the transfer chamber 108.

With the substrate in the load lock chamber 104 or 106 that has been pumped down, the transfer robot 112 transfers the substrate from the load lock chamber 104 or 106 into the transfer chamber 108 through the port 144 or 146. The transfer robot 112 is then capable of transferring the substrate to and/or between any of the processing chambers 120, 122 through the respective ports 152, 154 for processing and the holding chambers 116, 118 through the respective ports 148, 150 for holding to await further transfer. Similarly, the transfer robot 114 is capable of accessing the substrate in the holding chamber 116 or 118 through the port 156 or 158 and is capable of transferring the substrate to and/or between any of the processing chambers 124, 126, 128, 130 through the respective ports 160, 162, 164, 165 for processing and the holding chambers 116, 118 through the respective ports 156, 158 for holding to await further transfer. The transfer and holding of the substrate within and among the various chambers can be in the low pressure or vacuum environment provided by the gas and pressure control system.

The processing chambers 120, 122, 124, 126, 128, 130 can be any appropriate chamber for processing a substrate. In one or more examples, the processing chamber 120 can be capable of performing an etch process, the processing chamber 122 can be capable of performing a cleaning process, the processing chamber 124 can be capable of performing a selective removal process, and the processing chambers 126, 128, 130 can be capable of performing respective epitaxial growth processes. The processing chamber 120 may be a Selectra™ Etch chamber available from Applied Materials of Santa Clara, Calif. The processing chamber 122 may be a SiCoNi™ Pre-clean chamber available from Applied Materials of Santa Clara, Calif. The processing chamber 126, 128, or 130 may be a Centura™ Epi chamber available from Applied Materials of Santa Clara, Calif. The present disclosure contemplates that the deposition operations and the etching operations described herein can be conducted in the same chamber (such as in the same deposition chamber) or can be conducted in multiple chambers.

A system controller 168 is coupled to the multi-chamber processing system 100 for controlling the multi-chamber processing system 100 or components thereof. For example, the system controller 168 may control the operation of the multi-chamber processing system 100 using a direct control of the chambers 104, 106, 108, 110, 116, 118, 120, 122, 124, 126, 128, 130 of the multi-chamber processing system 100 or by controlling controllers associated with the chambers 104, 106, 108, 110, 116, 118, 120, 122, 124, 126, 128, 130. In operation, the system controller 168 enables data collection and feedback from the respective chambers to coordinate performance of the multi-chamber processing system 100.

The system controller 168 generally includes a central processing unit (CPU) 170, memory 172, and support circuits 174. The CPU 170 may be one of any form of a general-purpose processor that can be used in an industrial setting. The memory 172, or non-transitory computer-readable medium, is accessible by the CPU 170 and may be one or more of memory such as read only memory (ROM) (e.g., electrically erasable programmable read-only memory (EEPROM)), flash memory (e.g., flash drive), floppy disk, hard disk, random access memory (RAM) (e.g., non-volatile random access memory (NVRAM), dynamic random access memory (DRAM), static RAM (SRAM), and synchronous dynamic RAM (SDRAM (e.g., DDR1, DDR2, DDR3, DDR3L, LPDDR3, DDR4, LPDDR4, and the like)), or any other form of digital storage, local or remote. The support circuits 174 are coupled to the CPU 170 and may comprise cache, clock circuits, input/output subsystems, power supplies, and the like. The various methods disclosed herein (such as the method 300) may generally be implemented under the control of the CPU 170 by the CPU 170 executing computer instruction code stored in the memory 172 (or in memory of a particular processing chamber) as, for example, a software routine. When the computer instruction code is executed by the CPU 170, the CPU 170 controls the chambers to perform processes in accordance with the various methods.

The instructions stored in the memory 172 of the system controller 168 can include one or more machine learning/artificial intelligence algorithms that can be executed in addition to the operations described herein. As an example, a machine learning/artificial intelligence algorithm executed by the system controller 168 can generate, prioritize, accept, and/or reject signal profiles and/or data (such as metrology data and/or substrate map data) used in relation to the method 300. The machine learning/artificial intelligence algorithm can account for previous operational runs to monitor and update the signal profiles and/or data. The machine learning/artificial intelligence algorithm can optimize process parameter(s) of process recipes. The one or more machine learning/artificial intelligence algorithms can use, for example, a regression model (such as a linear regression model) or a clustering technique to estimate optimized parameters and/or optimized values for signal profiles and/or data. The algorithm(s) can be unsupervised or supervised. In one or more embodiments, the system controller 168 automatically conducts the operations described herein without the use of one or more machine learning/artificial intelligence algorithms. In one or more embodiments, the system controller 168 compares measurements to data in a look-up table and/or a library to optimize process parameters. The system controller 168 can store measurements as data in the look-up table and/or the library.

Other processing systems can be in other configurations. For example, more or fewer processing chambers may be coupled to a transfer apparatus. In the illustrated example, the transfer apparatus includes the transfer chambers 108, 110 and the holding chambers 116, 118. In one or more examples, more or fewer transfer chambers (e.g., one transfer chamber) and/or more or fewer holding chambers (e.g., no holding chambers) may be implemented as a transfer apparatus in a processing system.

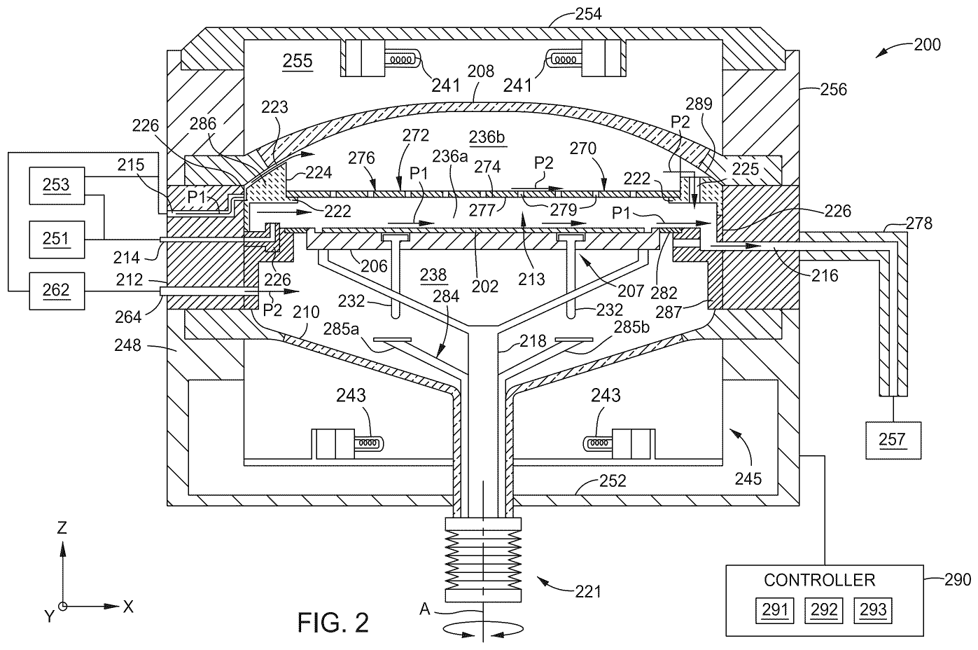

FIG. 2 is a partial schematic side cross-sectional view of a processing chamber 200 in accordance with one or more embodiments of the present disclosure. The processing chamber 200 provides one example of a process chamber in which the pulse-etch-purge process can be performed. The processing chamber 200 is a deposition chamber. In one or more embodiments, the processing chamber 200 is an epitaxial deposition chamber. In one or more embodiments, the processing chamber 200 is utilized to grow an epitaxial film on a substrate 202. The processing chamber 200 creates a crossflow of precursors across a top surface of the substrate 202. The processing chamber 200 is shown in a processing condition in FIG. 2. The processing chamber 200 may be the processing chamber 124, 126, 128, or 130 shown in FIG. 1.

The processing chamber 200 includes an upper body 256, a lower body 248 disposed below the upper body 256, a flow module 212 disposed between the upper body 256 and the lower body 248. The upper body 256, the flow module 212, and the lower body 248 form a chamber body. Disposed within the chamber body is a substrate support 206, an upper plate 208 (such as an upper window and/or an upper dome), a lower plate 210 (such as a lower window and/or a lower dome), a plurality of upper heat sources 241, and a plurality of lower heat sources 243. As shown, a controller 290 is in communication with the processing chamber 200 and is used to control processes and methods, such as the operations of the methods described herein. The present disclosure contemplates that each of the heat sources described herein can include one or more of: lamp(s), resistive heater(s), light emitting diode(s) (LEDs), and/or laser(s). The present disclosure contemplates that other heat sources can be used.

The substrate support 206 is disposed between the upper plate 208 and the lower plate 210. The substrate support 206 includes a support face that supports the substrate 202. The plurality of upper heat sources 241 are disposed between the upper window and a lid 254. The plurality of upper heat sources 241 form a portion of the upper heat source module 255. The lid 254 may include a plurality of sensors disposed therein or thereon for measuring the temperature within the processing chamber 200. The plurality of lower heat sources 243 are disposed between the lower plate 210 and a floor 252. The plurality of lower heat sources 243 form a portion of a lower heat source module 245. In one or more embodiments, the upper plate 208 is an upper dome and is formed of an energy transmissive material, such as quartz. In one or more embodiments, the lower plate 210 is a lower dome and is formed of an energy transmissive material, such as quartz. A pre-heat ring 282 is disposed outwardly of the substrate support 206. A stop 284 includes a plurality of arms 285a, 285b that each include a lift pin stop on which at least one of the lift pins 232 can rest when the substrate support 206 is lowered (e.g., lowered from a process position to a transfer position).

The internal volume has the substrate support 206 disposed therein. The substrate support 206 includes a top surface on which the substrate 202 is disposed. The substrate support 206 is attached to a shaft 218. The shaft 218 is connected to a motion assembly 221. The motion assembly 221 includes one or more actuators and/or adjustment devices that provide movement and/or adjustment for the shaft 218 and/or the substrate support 206.

The substrate support 206 may include lift pin perforations 207 disposed therein. The lift pin perforations 207 are sized to accommodate a lift pin 232 for lifting of the substrate 202 from the substrate support 206 either before or after a deposition process is performed.

A chamber kit 270 includes a plate apparatus 272. The plate apparatus 272 includes an isolation plate 274 having a first outer face 276 and a second outer face 277 opposing the first outer face 276. The second outer face 277 faces the substrate support 206. The isolation plate 274 can have one or more holes 279 extending from the first outer face 276 to the second outer face 277.

The chamber body includes a first liner 286 and a second liner 287. The second liner 287 is disposed below the first liner 286. The pre-heat ring 282 is supported on a ledge of the second liner 287. The first liner 286 includes a curved section 289 (e.g., an annular section). One or more inlet openings 223 extending to an inner surface 224 of the curved section 289 are on a first side of the first liner 286, and one or more second outlet openings 225 are on a second side of the first liner 286. The one or more inlet openings 223 can be between the first liner 286 and the upper plate 208. The first liner 286 includes one or more ledges 222 sized and shaped to support an outer region of the plate apparatus 272.

In the embodiment shown in FIG. 2, a lowermost end of the plate apparatus 272 is aligned above a lowermost end of the first liner 286. In one or more embodiments, as shown in FIG. 2, the lowermost end of the plate apparatus 272 is part of the second outer face 277, and the lowermost end of the first liner 286 is part of an extension.

At least part of the plate apparatus 272 is in the shape of a disc, and at least part of the curved section 289 is in the shape of a ring. It is contemplated, however, that the plate apparatus 272 and/or the curved section 289 can be in the shape of a rectangle, or other geometric shapes. The plate apparatus 272 at least partially fluidly isolates an upper portion 236b of an internal volume from a lower portion 236a of the internal volume. The lower portion 236a is a processing volume. The plate apparatus 272 at least partially defines the processing volume between the plate apparatus 272 and the substrate support 206.

In one or more embodiments, the isolation plate 274 is omitted, and the processing volume spans the open space between the substrate 202 and the upper plate 208.

The flow module 212 (which can define at least part of one or more sidewalls of the processing chamber 200) includes one or more first gas inlets 214 in fluid communication with the lower portion 236a (e.g., the processing volume) of the internal volume. The flow module 212 includes one or more second inlet openings 215 in fluid communication with the upper portion 236b of the internal volume. The one or more first gas inlets 214 are in fluid communication with one or more flow gaps between the first liner 286 and the second liner 287. One or more inject blocks 226 having one or more flow openings formed therein can be disposed in one or more flow gaps between the first liner 286 and the second liner 287. The one or more second gas inlets 215 are in fluid communication with the one or more inlet openings 223 above the first liner 286. The one or more first gas inlets 214 are fluidly connected to one or more process gas sources 251 and one or more etchant gas sources 253. The plurality of purge gas inlets 264 are fluidly connected to one or more purge gas sources 262. The one or more gas exhaust outlets 216 are fluidly connected to an exhaust pump 257. One or more process gases supplied using the one or more process gas sources 251 can include one or more reactive gases (such as one or more of silicon-containing, phosphorus-containing, and/or germanium-containing gases, and/or one or more carrier gases (such as one or more of nitrogen (N₂) and/or hydrogen (H₂)). One or more purge gases supplied using the one or more purge gas sources 262 can include one or more inert gases (such as one or more of argon (Ar), helium (He), and/or nitrogen (N₂)). One or more cleaning gases and/or etchant gases supplied using the one or more etchant gas sources 253 can include one or more of hydrogen and/or chlorine (such as hydrochloric acid (HCl) and/or chlorine gas (Cl₂)). The HCl and the chlorine gas can be injected at different locations along the processing chamber. In one or more embodiments, the HCl and/or Cl2 can be injected into the lower portion 236a via the one or more first gas inlets 214. In one or more embodiments, the HCl and/or Cl2 can be injected into the upper portion 236b via the one or more second gas inlets 215, and travel through the holes 279 in the isolation plate 274 into the lower portion 236a. In one or more embodiments, the one or more process gases include silicon hydrides (such as one or more silanes and/or one or more chlorinated silanes), germanium (such as germane (GeH₄)), boron (such as diborane (B₂H₆)), and/or phosphine (PH₃).

The one or more gas exhaust outlets 216 are further connected to or include an exhaust system 278. The exhaust system 278 fluidly connects the one or more gas exhaust outlets 216 and the exhaust pump 257. The exhaust system 278 can assist in the controlled deposition of a layer on the substrate 202. The exhaust system 278 is disposed on the opposite side of the processing chamber 200 relative to the flow module 212.

During a deposition operation (e.g., an epitaxial growth operation), the one or more process gases P1 flow through the one or more first gas inlets 214, through the one or more gaps, and into the lower portion 236a to flow horizontally over the substrate support 206 and the substrate 202 and to the one or more gas exhaust outlets 216. During the deposition operation, one or more purge gases P2 flow through the one or more second gas inlets 215, through the one or more inlet openings 223 of the first liner 286, and into the upper portion 236b. The one or more purge gases P2 flow simultaneously with the flowing of the one or more process gases P1. The flowing of the one or more purge gases P2 through the upper portion 236b facilitates reducing or preventing flow of the one or more process gases P1 into the upper portion 236b that would contaminate the upper portion 236b. The one or more process gases P1 are exhausted through exhaust gaps between the first liner 286 and the second liner 287, and through the one or more gas exhaust outlets 216. The one or more purge gases P2 are exhausted through the one or more second outlet openings 225, through the same exhaust gaps between the first liner 286 and the second liner 287, and through the same one or more gas exhaust outlets 216 as the one or more process gases P1. The present disclosure contemplates that that one or more purge gases P2 can be separately exhausted through one or more second gas exhaust outlets that are separate from the one or more gas exhaust outlets 216.

The present disclosure also contemplates that one or more purge gases can be supplied to the purge volume 238 (through the plurality of purge gas inlets 264) during the deposition operation and exhausted from the purge volume 238.

The controller 290 generally includes a central processing unit (CPU) 291, memory 292, and support circuits 293. The CPU 291 may be one of any form of a general-purpose processor that can be used in an industrial setting. The memory 292, or non-transitory computer-readable medium, is accessible by the CPU 291 and may be one or more of memory such as read only memory (ROM) (e.g., electrically erasable programmable read-only memory (EEPROM)), flash memory (e.g., flash drive), floppy disk, hard disk, random access memory (RAM) (e.g., non-volatile random access memory (NVRAM), dynamic random access memory (DRAM), static RAM (SRAM), and synchronous dynamic RAM (SDRAM (e.g., DDR1, DDR2, DDR3, DDR3L, LPDDR3, DDR4, LPDDR4, and the like)), or any other form of digital storage, local or remote. The support circuits 293 are coupled to the CPU 291 and may include cache, clock circuits, input/output subsystems, power supplies, and the like. The various methods disclosed herein (such as the method 300) may generally be implemented under the control of the CPU 291 by the CPU 291 executing computer instruction code stored in the memory 292 (or in memory of a particular processing chamber) as, for example, a software routine. When the computer instruction code is executed by the CPU 291, the CPU 291 controls the chambers to perform processes in accordance with the various methods.

The instructions stored in the memory 292 of the controller 290 can include one or more machine learning/artificial intelligence algorithms that can be executed in addition to the operations described herein. As an example, a machine learning/artificial intelligence algorithm executed by the controller 290 can generate, prioritize, accept, and/or reject signal profiles and/or data (such as metrology data and/or substrate map data) used in relation to the method 300. The machine learning/artificial intelligence algorithm can account for previous operational runs to monitor and update the signal profiles and/or data. The machine learning/artificial intelligence algorithm can optimize process parameter(s) of process recipes. The one or more machine learning/artificial intelligence algorithms can use, for example, a regression model (such as a linear regression model) or a clustering technique to estimate optimized parameters and/or optimized values for signal profiles and/or data. As an example, the one or more machine learning/artificial intelligence algorithms can optimize the exemplary parameter values described herein (such as the method 300). The algorithm(s) can be unsupervised or supervised. In one or more embodiments, the controller 290 automatically conducts the operations described herein without the use of one or more machine learning/artificial intelligence algorithms. In one or more embodiments, the controller 290 compares measurements to data in a look-up table and/or a library to optimize process parameters. The controller 290 can store measurements as data in the look-up table and/or the library.

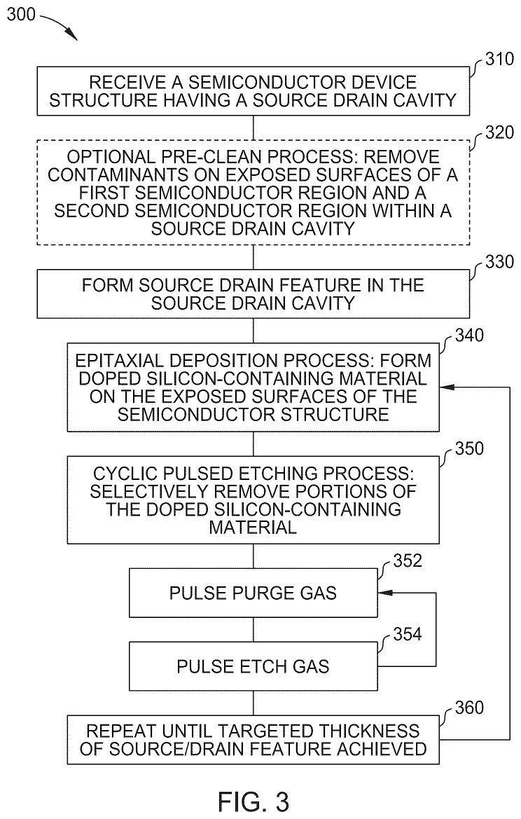

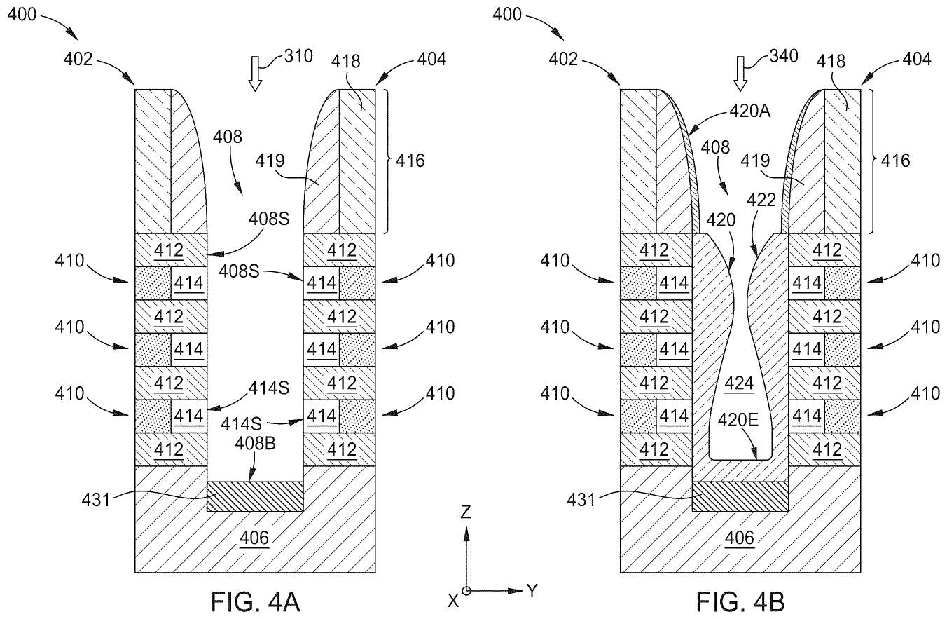

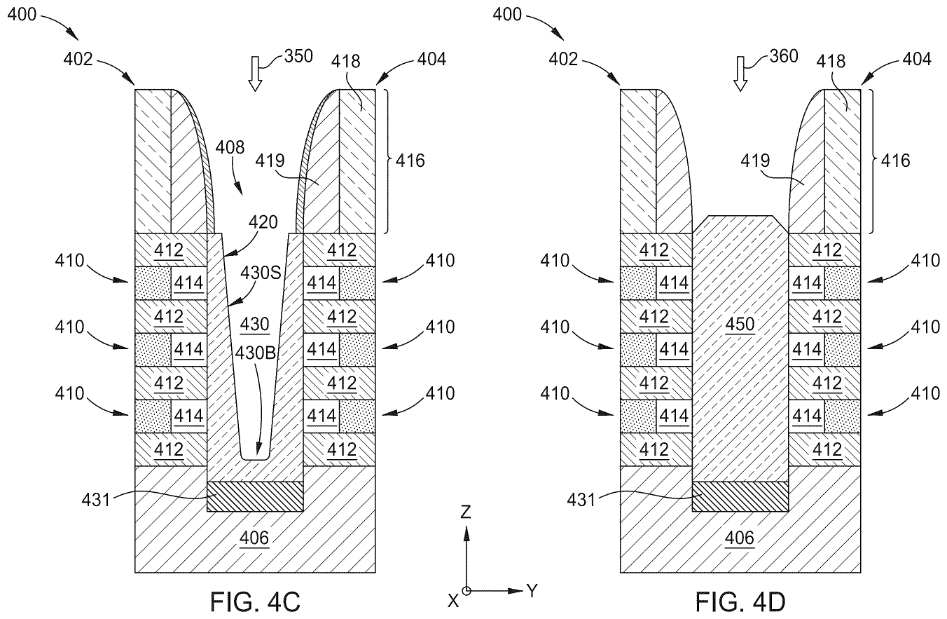

FIG. 3 illustrates an exemplary flow chart of a method 300 in accordance with one or more embodiments of the present disclosure. FIGS. 4A-4D illustrate schematic side views of various stages of manufacturing a semiconductor device structure 400 according to the method 300 of FIG. 3 in accordance with one or more embodiments of the present disclosure. FIGS. 4A-4D illustrate side views taken along the y-direction or y-cut of the semiconductor device structure 400. Although FIGS. 4A-4D are described in relation to the method 300, it will be appreciated that the semiconductor device structure 400 disclosed in FIGS. 4A-4D are not limited to the method 300 but instead may stand alone as structures independent of the method 300. Similarly, although the method 300 is described in relation to FIGS. 4A-4D, it will be appreciated that the method 300 is not limited to the semiconductor device structure 400 disclosed in FIGS. 4A-4D but instead may stand alone independent of the semiconductor device structure 400 disclosed in FIGS. 4A-4D. FIGS. 4A-4D illustrate only partial schematic views of the semiconductor device structure, and the semiconductor device structure 400 may contain any number of additional layers and/or additional materials common to semiconductor device structures, which are not shown for the sake of brevity. It should also be noted that although the method 300 illustrated in FIG. 3 is described sequentially, other process sequences that include one or more operations that have been omitted and/or added, and/or have been rearranged in another desirable order, fall within the scope of the embodiments of the disclosure provided herein. The method 300 may be performed using any suitable system, for example, the multi-chamber processing system 100. In one or more embodiments, the method 300 or parts of the method 300 are performed in the processing chamber 200.

Referring to FIG. 4A, at operation 310 a semiconductor device structure 400 having a trench 408 in which a S/D region is formed is received. The semiconductor device structure 400 may be or be part of a multi-gate device with three-dimensional architecture, such as fin-based semiconductor devices including nano-FETs and gate-all-around (GAA) transistor devices. The semiconductor device structure 400 includes a first semiconductor region 402 also referred to as a first fin structure and a second semiconductor region 404 also referred to as a second fin structure formed on a substrate 406. The first semiconductor region 402 and the second semiconductor region 404 are separated by a feature, such as the trench 408 or a source/drain cavity, which exposes the substrate 406. In one or more embodiments, a portion of the trench 408 extends into the substrate 406 as shown in FIG. 4A.

The term “substrate” as used herein refers to a layer of material that serves as a basis for subsequent processing operations and includes a surface to be cleaned. The substrate may be a silicon-based material, or any suitable insulating materials or conductive materials as needed. The substrate may include a material such as crystalline silicon (e.g., Si<100> or Si<211>), silicon oxide, strained silicon, silicon germanium, doped or undoped polysilicon, doped or undoped silicon wafers and patterned or non-patterned wafers, silicon on insulator (SOI), carbon doped silicon oxides, silicon nitride, doped silicon, germanium, gallium arsenide, glass, or sapphire.

As shown in FIG. 4A, the first semiconductor region 402 and the second semiconductor region 404 each include first semiconductor layer(s) 410 and second semiconductor layer(s) 412 that are alternately and repeatedly stacked on the substrate 406. FIG. 4A illustrates a side view taken along the y-direction or y-cut of the semiconductor device structure 400. Although the example shown in FIG. 4A shows three pairs, each pair including the first semiconductor layer 410 and the second semiconductor layer 412, the number of pairs may be varied based on different process needs with or without the first semiconductor layer(s) 410 and the second semiconductor layer(s) 412 being needed. The first semiconductor layer(s) 410 are formed of a first material having etch selectivity to a second material of which the second semiconductor layer(s) 412 are formed (i.e., an etch rate of the first material is higher than an etch rate of the second material). The etch selectivity (i.e., a ratio of the etch rate of the first material to the etch rate of the second material) is between about 10:1 to 200:1. Example combinations of the first material and the second material include silicon germanium (SiGe)/silicon (Si), silicon germanium (SiGe)/germanium (Ge), and germanium tin (GeSn)/silicon (Si). In one or more embodiments, the first semiconductor layer(s) 410 are or include SiGe and the second semiconductor layer(s) 412 are or include silicon, for example, crystalline silicon.

The first semiconductor layer(s) 410 may be selectively etched to form indentations at the end of the first semiconductor layer(s) 410 facing the trench 408, in each of which an inner spacer 414 is formed. The inner spacer 414 may be formed of dielectric material, such as silicon nitride (Si₃N₄), silicon oxynitride (SiON), or silicon oxycarbide (SiOCN). Although the outer sidewalls of the inner spacer 414 is illustrated as being flush with sidewalls of the second semiconductor layer(s) 412, the outer sidewalls of the inner spacer 414 may extend beyond or be recessed from sidewalls of the second semiconductor layer(s) 412.

The second semiconductor layer(s) 412 may serve as channels having a width of between several nanometers and several tens of nanometers. The first semiconductor layer(s) 410 and the second semiconductor layer(s) 412 can be nanostructures, for example, nanowires or nanosheets.

The first semiconductor layer(s) 410 and the second semiconductor layer(s) 412 may be formed using any suitable deposition technique, such as chemical vapor deposition (CVD), atomic layer deposition (ALD), or physical vapor deposition (PVD), and the trench 408 is formed by a patterning technique, such as a lithography and etch process. The first semiconductor layer(s) 410 and the second semiconductor layer(s) 412 may each have thickness in a range from about 3 nm to about 25 nm, for example, about 10 nm. The selective etching of the first semiconductor layer(s) 410 may be performed by any appropriate etch process, such as a dry plasma etch process.

In one or more embodiments, the semiconductor device structure 400 further includes a dummy gate structure (also referred to as a “dielectric layer”) 416 formed over at least a portion of each of the first semiconductor region 402 and the second semiconductor region 404. The dummy gate structure 416 includes a dummy gate 418. The dummy gate 418 may be or include a conductive or nonconductive material and may be selected from amorphous silicon, doped or undoped polycrystalline silicon (polysilicon), polycrystalline silicon-germanium (poly-SiGe), silicon oxide, metallic nitrides, metallic silicides, metallic oxides, and metals. The dummy gate 418 may be formed using any suitable techniques such as physical vapor deposition (PVD), plasma enhanced chemical vapor deposition (PECVD), CVD, ALD, or the like.

The dummy gate structure 416 may further include one or more spacers 419. The spacers 419 may function as a spacer for forming self-aligned source/drain regions. The spacers 419 may be formed along the sidewalls of the dummy gate 418. The spacers 419 may be formed of silicon oxycarbonitride, silicon oxide, silicon nitride, silicon oxynitride, or the like, using any suitable techniques such as thermal oxidation, or deposited by PECVD, CVD, ALD, or the like.

The trench 408 is defined by a pair of opposing sidewall surfaces 408S and a bottom surface 408B. The sidewall surfaces 408S may be defined by the dummy gate structure 416 and the alternating pairs of the first semiconductor layer(s) 410/inner spacers 414 and the second semiconductor layer(s) 412. In one or more embodiments, the bottom surface 408B of the trench 408 is defined by the substrate 406. In one or more other embodiments, the bottom surface 408B is defined by a dielectric material, for example, a bottom dielectric isolation (BDI) layer 431.

Referring to FIG. 4A, optionally at operation 320, a pre-clean process is performed. The pre-clean process of operation 320 may be performed in a processing chamber, such as the processing chamber 122 shown in FIG. 1 or the processing chamber 200 shown in FIG. 2. In some embodiments, the pre-clean process of operation 320 and the deposition process of operation 330 are performed in-situ in the same processing chamber, to minimize regrowth of oxide layers.

The pre-clean process is configured to remove contaminants, such as native oxide layers, or patterning residues (e.g., fluorocarbons) formed on the exposed surfaces of the first semiconductor region 402 and the second semiconductor region 404 within the trench 408.

In one or more embodiments, the pre-clean etch process includes a wet etch process, using a cleaning solution, such as a hydrofluoric acid (HF)-last type cleaning solution, ozonated water cleaning solution, HF and hydrogen peroxide (H₂O₂) solution, and/or other suitable cleaning solution. The cleaning solution may be heated.

In one or more embodiments, the pre-clean process includes an isotropic plasma etching process, such as a SiCoNi™ dry chemical etching process, using a plasma formed from a gas including ammonia (NH₃), nitrogen trifluoride (NF₃), hydrogen fluoride (HF), or a combination thereof, and a carrier gas, such as nitrogen (N₂), hydrogen (H₂), or a combination thereof. The dry chemical etching process is selective for oxide layers, and thus does not readily etch silicon, germanium, or nitride layers regardless of whether the layers are amorphous, crystalline or polycrystalline. Selectivity of the dry chemical etching process for oxide versus silicon or germanium is at least about 3:1, and usually 5:1 or better, sometimes 10:1. The dry chemical etching process is also highly selective of oxide versus nitride. The selectivity of the dry chemical etching process versus nitride is at least about 3:1, usually 5:1 or better, sometimes 10:1.

In one or more embodiments, the pre-clean process includes a thermal etching process. The one or more process gases etch the surface of the substrate to remove oxide impurities. The one or more process gases include hydrogen fluoride (HF), ammonia (NH₃), water, or an alcohol. In one or more embodiments, the pre-clean process is a thermal process.

In one or more embodiments, the pre-clean process includes an anisotropic remote plasma assisted dry etch process, such as a reactive ion etching (RIE) process, using a plasma formed from a gas including argon (Ar), helium (He), or a combination thereof. The plasma effluents directionally bombard and remove contaminants on the exposed surfaces of the first semiconductor region 402 and the second semiconductor region 404 within the trench 408.

In one or more embodiments, the pre-clean process may include an inductively coupled plasma (ICP) etching process, using a plasma formed from a gas including chlorine (Cl₂) and hydrogen (H₂), and a carrier gas including argon (Ar) and helium (He).

In one or more embodiments, the pre-clean process includes exposing the semiconductor device structure 400 to atomic hydrogen radicals.

In one or more embodiments, the pre-clean process further includes exposing the semiconductor device structure 400 to a thermal annealing process at a temperature of 600 degrees Celsius or higher, for example, in a range from about 650 degrees Celsius to about 900 degrees Celsius. The cleaning process can remove surface oxide, carbon, and debris to ensure a clean semiconductor surface, which facilitates growth of high-quality epitaxial layers.

Referring to FIGS. 4A-4D, at operation 330, a source/drain feature 450 is formed in the trench 408 or the source/drain cavity. The source/drain feature 450 fills or partially fills the trench 408 to a targeted thickness in between the first semiconductor region 402 and the second semiconductor region 404. The composition of the source/drain feature 450 depends on the conductivity type of the semiconductor device structure 400. If the semiconductor device structure 400 is an n-type structure, the source/drain feature 450 may include silicon (Si) doped with an n-type dopant such as phosphorous (P), antimony (Sb), or arsenic (As). If the semiconductor device structure 400 is a p-type structure, the source/drain feature 450 may include silicon (Si) or SiGe doped with an p-type dopant such as boron (B) or gallium (Ga). In some embodiments, as is shown in FIG. 4B, FIG. 4C, and FIG. 4D the source/drain feature 450 includes multiple epitaxial layers each formed by an epitaxial process. The source/drain feature 450 may be epitaxially and selectively formed from the exposed sidewall surfaces 408S of the second semiconductor layer(s) 412, the inner spacers 414 and the bottom surface 408B. Suitable epitaxial processes include vapor-phase epitaxial (VPE), ultra-high vacuum CVD (UHV-CVD), molecular beam epitaxy (MBE), low pressure CVD (LPCVD), plasma epitaxy, and/or other suitable processes. The epitaxial growth process uses gaseous precursors, which interact with the material of the substrate 406 and the materials of the first semiconductor layer(s) 410 and the second semiconductor layer(s) 412.

In one or more embodiments, the source/drain feature 450 is epitaxially grown by a cyclic deposition/pulsed etching process including an epitaxial deposition process performed during operation 340 followed by a cyclic pulse etching process performed during operation 350. The cyclic pulse etching process of operation 350 can include pulsing a purge gas at operation 352 followed by pulsing an etchant gas during operation 354 or pulsing an etchant gas followed by pulsing a purge gas. At operation 360, the epitaxial deposition process and the pulse etching process are repeated for a number of cycles until the source/drain feature 450 achieves a targeted thickness.

Referring to FIG. 4B, at operation 340, an epitaxial deposition process is performed to form a doped silicon-containing material 420 on the exposed surfaces of the semiconductor device structure 400 (i.e., exposed surfaces of the first semiconductor region 402 and the second semiconductor region 404 within the trench 408, and the dummy gate structure 416). The epitaxial deposition process may include any appropriate deposition process, such plasma enhanced chemical vapor deposition (PECVD), low pressure chemical vapor deposition (LPCVD), epitaxy process, or the like, in a processing chamber, such as the processing chamber 126, 128, or 130 shown in FIG. 1, or the processing chamber 200 shown in FIG. 2. The doped silicon-containing material 420 may include both doped epitaxial silicon portions 420E formed over crystalline surfaces and doped amorphous silicon portions 420A formed over non-crystalline surfaces.

The doped silicon-containing material 420 may be doped with p-type dopants such as boron (B) or gallium (Ga) with the concentration depending upon the desired conductive characteristic of the source/drain feature 450 to be formed in the trench 408. The doped silicon-containing material 420 may be formed of silicon germanium (SiGe) with a high germanium (Ge) concentration, for example, between about 5% and about 60%, to minimize parasitic resistance. The doped silicon-containing material 420 may contain carbon (C) with a concentration of less than about 1%, which may be used for subsequent dopant diffusion control in the source/drain feature 450.

In one or more embodiments, the doped silicon-containing material 420 is doped with n-type dopants such as phosphorus (P), antimony (Sb), or arsenic (As) with the concentration depending upon the desired conductive characteristic of the source/drain feature 450 to be formed in the trench 408. The doped silicon-containing material 420 may be formed of silicon germanium (SiGe) with a low germanium (Ge) concentration, for example, less than about 5%.

The deposition gas includes a silicon-containing precursor, optionally a germanium-containing precursor, and a dopant source. The silicon-containing precursor may include silane (SiH₄), disilane (Si₂H₆), trisilane Si₃H₈, tetrasilane (Si₄H₁₀), methylsilane (CH6Si), dimethylsilane (C2H8Si), dichlorosilane (SiH2Cl2), or a combination thereof. The germanium-containing precursor may include germane (GeH₄), germanium tetrachloride (GeCl₄), and digermane (Ge₂H₆). To form an n-type amorphous silicon-containing layer, the dopant source may include n-type dopants such as phosphorus (P), antimony (Sb), arsenic (As). The dopant source may include a precursor tert-butyl phosphine (C4H21P), phosphine (PH₃), phosphorus trichloride (PCl₃), triisobutylphosphine ([(CH₃)₃C]₃P), antimony trichloride (SbCl₃), Sb(C₂H₅)₅, arsine (AsH₃), arsenic trichloride (AsCl₃), tertiarybutylarsine (AsC₄H₂₁). To form a p-type silicon-containing layer, the dopant source may include p-type dopants such as boron (B), or gallium (Ga). The dopant source may include a precursor diborane (B₂H₆), or trimethylgallium Ga(CH₃)₃. It should be noted that dopants may enhance etch selectivity in a subsequent cyclic pulse-etch-purge process of operation 350.

In one or more embodiments, the epitaxial deposition process of operation 340 is a selective epitaxial deposition process. Not to be bound by theory but it is believed that selective epitaxial deposition processes is less susceptible to early merging of the sidewall film and also reduces the process complexity. The selective epitaxial deposition process includes co-flowing an etchant gas with the deposition and dopant gases. The etchant gas can be selected from HCl, Cl2, HBr, PCl3, AsCl3, GeCl4, or a combination thereof.

In one or more embodiments, the epitaxial deposition process of operation 340 is a non-selective epitaxial deposition process. The non-selective epitaxial deposition process includes flowing the deposition and dopant gases without co-flowing an etchant gas.

The deposition gas and the dopant gas may be provided with a carrier gas. The carrier gas may have a flow rate in a range from about 1 SLM to about 100 SLM, or in a range from about 2 SLM to about 30 SLM, or in a range from about 2 SLM to about 5 SLM. Suitable carrier gases include nitrogen (N2), hydrogen (H2), argon, helium, or combinations thereof. The carrier gas may be selected based on the reactants used and/or the process temperature during the soak process.

In one or more embodiments, the epitaxial deposition process of operation 340 includes flowing dichlorosilane, phosphine, and hydrogen.

During operation 340, a first pressure of an environment in a processing chamber in which the epitaxial growth is performed can be maintained in a range from about 100 Torr to about to about 500 Torr, or from about 200 Torr to about 400 Torr, or from about 200 Torr to about 300 Torr, or from about 300 Torr to about 400 Torr. A first temperature of the substrate 406 during the epitaxial growth can be maintained at about 550° C. or less, or at about 500° C. or less, or at about 450° C. or less, or at about 400° C. or less, and more particularly in a range from about 200° C. to about 500° C., or from about 300° C. to about 450° C., or from about 350° C. to about 400° C., or from about 400° C. to about 450° C.

As depicted in FIG. 4B, during epitaxial film growth of operation 340, the doped silicon-containing material 420 tends to form a thicker or overhang portion 422 on the top silicon pair of the second semiconductor layer(s) 412 leading to pinch-off and the formation of voids 424 within the source/drain feature 450.

In one or more embodiments, after the deposition process of operation 350, the processing gases can be evacuated or purged from the processing chamber using, for example, an exhaust pump. In one or more embodiments, the evacuation process includes decreasing the pressure of the environment from the first pressure to a second pressure and/or increasing the flow rate of the carrier gas while stopping the flow of the deposition gas and the dopant gas.

In one or more embodiments, after the deposition process of operation 340 and prior to the cyclic pulse etching process of operation 350, the temperature can be ramped from the first temperature to a second temperature for the cyclic pulse etching process. In one or more embodiments, the ramp process includes increasing the pressure from the first pressure to a second pressure for the cyclic pulse etching process. In some embodiments, the first pressure is the same as or similar to the second pressure.

Referring to FIG. 4C, at operation 350, a cyclic pulse etching process is performed. The pulse-etch-purge process selectively removes portions of the doped silicon-containing material 420. For example, the cyclic pulse-etch-purge process removes or reduces the thickness of the overhang portion 422 from the doped silicon-containing material 420 such that the modified doped silicon-containing material 420 defines a recess 430 that is U-shaped or V-shaped as shown in FIG. 3C. In one or more embodiments, as is shown in FIG. 4C, the recess 430 is defined by tapered sidewall surfaces(s) 430S, which increase in thickness as the tapered sidewall(s) approach the bottom surface 408B and a bottom surface 430B defining the recess 430 is curved or rounded.

The cyclic pulse etching process described can be performed using typical nMOS and pMOS process conditions. The temperature of the cyclic etching process can be either the same or different from the epitaxial deposition temperature. Pulsed etch pressure/purge pressure can be in a range from about 5 torr to about 600 torr. The pulsed etch gases can be provided in a carrier gas, for example, H2 or N2, at a flow rate in a range from about 500 sccm to 30 SLM. Etchant gases include but are not limited to (1) HCl, Cl2, HBr, and other suitable etchants compatible in the chamber design; (2) PCl3, AsCl3, GeCl4 as both etchant gas and P, As, and Ge source gas; (3) 1 or 2, with an etchant suppressor gas, for example, an additional Si and/or Ge source gases (SiH4, H2SiCl2, Si2H6, Si3H8, Si4H10, GeH4, Ge2H6, etc.); and (4) 1, 2, 3 types of gases can be injected (in the pulse mode) at the same time or (5) in any sequential order. In one or more embodiments, sequential order includes injecting deposition gas and etchant gases at different time slots in a pulsed way similar to an atomic layer deposition process. In one or more embodiments, the pulsed etchant gases can be laterally injected into the process chamber and purged out of the chamber on the exhaust side. In one or more other embodiments, the pulsed etchant gases can be vertically injected into the chamber through a top plate with holes, for example, a showerhead.

In one or more embodiments, the cyclic pulse etching process includes any appropriate etch process and is performed in-situ in the same chamber as the epitaxial deposition process of operation 340, such as the processing chamber 200 shown in FIG. 2. The cyclic pulse etching process includes a plurality of etch cycles that respectively include flowing purge gas at operation 352 for a first time period and flowing an etch gas at operation 354 for a second time period to etch the source drain material. In one or more embodiments the purge gas is hydrogen (H2), nitrogen (N2), argon (Ar), or a combination thereof. In one or more embodiments the purge gas is hydrogen (H2). In one or more embodiments, the purge gas of operation 352 flows at a higher flow rate than the etch gas of operation 354. In one or more embodiments, the etch gas flows at a flow rate of at least 500 sccm, such as about 600 sccm. The etch gas is flowed for an etch time and the purge gas is flowed for a purge time that is greater than the etch time. The purge gas flowing of operation 352 and the etch gas flowing of operation 354 can be conducted for at least 3 etch cycles, such as 10 to 40 etch cycles. The respective etch cycles can each include a pulse of purge gas at operation 352 and a pulse of etch gas at operation 354. In one or more embodiments, the cyclic pulse etching process includes a plurality of etch cycles that respectively include flowing the etch gas at operation 354 prior to flowing the purge gas at operation 352.

In one or more embodiments, the etch gas includes one or more of: hydrochloric acid (HCl), chlorine gas (Cl₂), hydrogen bromide (HBr), phosphorus trichloride (PCl₃), arsenic trichloride (AsCl₃), germanium trichloride (GeCl₄), and/or one or more other etch gases.

In one or more embodiments, the etchant gas includes one or more of a first etchant gas, a second etchant gas, and a third etchant gas. The first etchant gas functions as an etchant gas. The first etchant gas can include HCl, Cl2, HBr, or a combination thereof.

The second etchant gas functions as both an etchant gas and a source gas. The second etchant gas can include PCl3, AsCl3, GeCl4, or a combination thereof.

The third etchant gas includes additional silicon and/or germanium source gases, which can be used to tune the surface epi films lost during the pulse of etch gas. Suitable etchant suppressor gases include SiH4, H2SiCl2, Si2H6, Si3H8, Si4H10, GeH4, Ge2H6, or a combination thereof. The deposition source gases can be delivered sequentially to or simultaneously with the etch gases.

The etchant gas or a gas mixture of the etchant gases can be introduced into the processing volume along with a carrier gas. The carrier gas can include hydrogen, nitrogen, argon, or a combination thereof. In some embodiments, the carrier gas flows continuously such that the carrier gas functions as both a carrier gas during pulses of the etchant gases and a purge gas in between pulses of the etchant gases. The etchant gases can be introduced into the processing volume simultaneously, sequentially, or a combination of simultaneously and sequentially. In one or more embodiments, the first etchant gas, the second etchant gas, and/or the third etchant gas are pulsed into the processing volume simultaneously followed by a pulse of purge gas. For example, a pulse of the first etchant gas and the third etchant gas are followed by a pulse of purge gas. In one or more embodiments, the first etchant gas, the second etchant gas, and/or the third etchant gas are pulsed into the processing volume sequentially in any order. Each sequential pulse can be separated by a pulse of purge gas. The purge gas can be provided by continuously flowing a carrier gas while the etch gas is pulsed such that the carrier gas functions as the purge gas in between pulses of the etch gas. For example, pulse of first etchant gas/pulse of purge gas/pulse of second etchant gas/pulse of purge gas/pulse of third etchant gas/pulse of purge gas. Other combinations and sequences of gases are contemplated.

In one or more embodiments, the pulse etching cycle includes a pulse of any combination of the first etchant gas, the second etchant gas, and/or the third etchant gas followed by a pulse of purge gas. The pulse etching cycle may be repeated for a targeted number of cycles.

In one or more embodiments, the pulse etching cycle includes a pulse of third etchant gas in combination with either the first etchant gas or the second etchant gas followed by a pulse of purge gas. The pulse etching cycle may be repeated for a targeted number of cycles.

In one or more embodiments, the pulse etching cycle includes a pulse of the first etchant gas, the second etchant gas, or the third etchant gas followed by a pulse of purge gas followed by a pulse of the first etchant gas, the second etchant gas, or the third etchant gas, followed by a pulse of purge gas followed by a pulse of the first etchant gas, the second etchant gas, or the third etchant gas. In one example, the pulse etching cycle includes a pulse of the first etchant gas followed by a pulse of purge gas followed by a pulse of the second etchant gas followed by a pulse of purge gas followed by a pulse of the third etchant gas followed by a pulse of purge gas. The pulse etching cycle may be repeated for a targeted number of cycles.

In one or more embodiments, the etch gas of operation 354 includes HCl co-flowed in a carrier gas such as hydrogen (H₂) gas. In one or more embodiments, the carrier gas flows continuously and the etch gas is pulsed such that the carrier gas functions as the purge gas in between pulses of the etch gas.

In one or more embodiments, the pulse etch time is 5.0 seconds or less, such as 3.0 seconds or less, such as about 2.0 seconds. In one or more embodiments, the pulse purge time is 5.0 seconds or less. In one or more embodiments, the pulse purge time is at least 4.0 seconds, such as about 5.0 seconds.

In one or more embodiments, the pulse etch and/or pulse purge gases can be laterally injected into the process chamber and purged out of the chamber on the exhaust side. For example, referring to FIG. 2, the purge gas and/or etch gas can be injected from the one or more first gas inlets 214 directly into the lower portion 236a. In one or more other embodiments, the pulse etch and/or pulse purge gases can be vertically injected into the chamber through XT plate with (mesh holes), for example, a showerhead. For example, referring to FIG. 2, the purge gas and/or etch gas can be injected from the one or more second gas inlets 215 into the upper portion 236b and travel through the holes 279 in the isolation plate 274 into the lower portion 236a.

At operation 360, the epitaxial deposition process of operation 340 and the cyclic pulse-etch-purge process of operation 350 may be repeated in a cyclic dep/etch process until the source/drain feature 450 is formed within the trench 408, as shown in FIG. 4D. In one or more embodiments, the cyclic dep/etch process includes partial epitaxial deposition followed by multiple cycles of “pulse-etch-purge” followed by partial epitaxial deposition followed by multiple cycles of “pulsed-etch-purge” until the GAA is fully filled to a targeted thickness.

It should be noted that although FIGS. 4A-4D depict the cyclic etching process as part of a partial fill epitaxial process, the cyclic etching process is also applicable to a full fill epitaxial process. For example, in one or more other embodiments, operation 340 includes epitaxial full fill deposition followed by multiple cycles of the cyclic pulse etching process of operation 350 to reopen the epitaxial structure and remove voids followed by additional epitaxial deposition followed by multiple cycles of pulse etching until the GAA or FinFET recess is filled to a targeted thickness. In one or more embodiments, several cycles of the epitaxial full fill of operation 340 followed by the cyclic pulse etching process of operation 350 to reopen the film followed by the epitaxial full fill of the reopened film at operation 340 followed by the cyclic pulse etching of operation 350 to reopen the film until void-free or substantially void-free epitaxial full. The cyclic pulse etching process is designed to remove the epitaxial film from the top portion of the filled S/D material while there is much less etching toward the bottom portion of the S/D material.

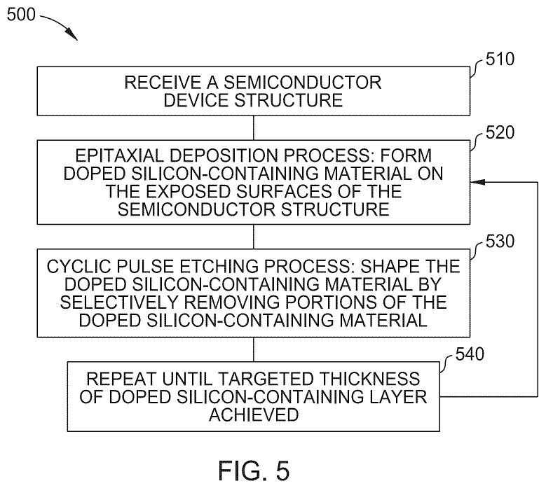

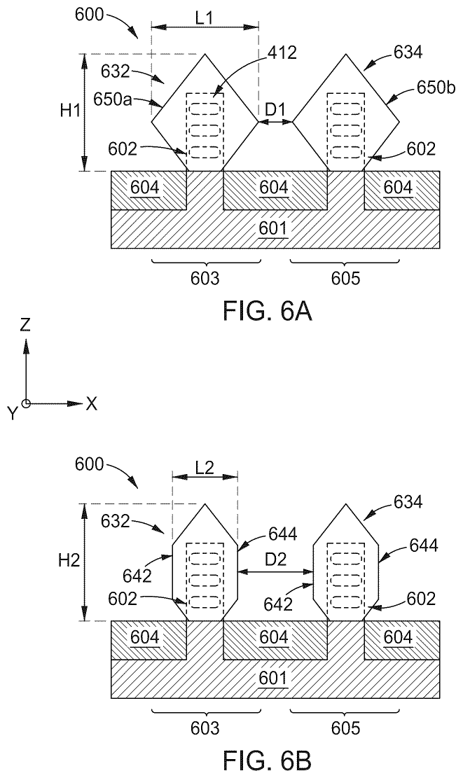

FIG. 5 illustrates an exemplary flow chart of another method 500 in accordance with one or more embodiments of the present disclosure. FIGS. 6A-6B illustrate side views of various stages of manufacturing a semiconductor device structure according to the method of FIG. 5 in accordance with one or more embodiments of the present disclosure. Although FIGS. 6A-6B are described in relation to the method 500, it will be appreciated that the semiconductor device structure 600 disclosed in FIGS. 6A-6B are not limited to the method 500 but instead may stand alone as structures independent of the method 500. Similarly, although the method 500 is described in relation to FIGS. 6A-6B, it will be appreciated that the method 500 is not limited to the semiconductor device structure 400 disclosed in FIGS. 6A-6B but instead may stand alone independent of the semiconductor device structure 600 disclosed in FIGS. 6A-6B. FIGS. 6A-6B illustrate only partial schematic views of the semiconductor device structure, and the semiconductor device structure 600 may contain any number of additional layers and/or additional materials common to semiconductor device structures, which are not shown for the sake of brevity. It should also be noted that although the method 500 illustrated in FIG. 5 is described sequentially, other process sequences that include one or more operations that have been omitted and/or added, and/or have been rearranged in another desirable order, fall within the scope of the embodiments of the disclosure provided herein. The method 500 may be performed using any suitable system, for example, the multi-chamber processing system 100. In one or more embodiments, the method 500 or parts of the method 500 are performed in the processing chamber 200.

The method 500 includes another embodiment in which the cyclic pulse etching process described in operation 350 is used for shaping epitaxial features. The cyclic pulse etching process of the method 500 is used for shaping epitaxial features, for example, epitaxial features formed in a FinFET or GAA FET structure. In one or more embodiments, FIGS. 6A-6B illustrate side views taken along the x-direction or x-cut of the semiconductor device structure 400. In other embodiments, FIGS. 6A-6B illustrate side views of a GAA FET structure. The method 500 may be performed simultaneously with the method 300. For example, in one or more embodiments, the cyclic pulse etching of operation 350 not only removes epitaxial material from the epitaxial features in the y-cut shown in FIG. 4A-4D but also shapes the epitaxial features in the x-cut shown in FIGS. 6A-6B. In one or more other embodiments, the method 300 and the method 500 are performed sequentially. For example, after the targeted thickness of the source/drain feature 450 is achieved, the method 500 is performed to shape the epitaxial features along the x-cut.

Referring to FIG. 6A, at operation 510, a semiconductor device structure 600 is received. The semiconductor device structure 600 can be a FinFET or GAA FET structure. The substrate 601 may be a silicon substrate, a germanium substrate, or a substrate formed from other semiconductor materials. The substrate 601 may be similar to or be the substrate 406. In one or more embodiments, the substrate 601 includes p-type or n-type dopants doped therein. If the semiconductor device structure 600 is a FinFET structure, the substrate 601 may include a plurality of semiconductor fins 602, shown in phantom, formed thereon isolated by shallow trench isolation (STI) structures 604. The STI structures 604 may be formed by an insulating material, such as a silicon oxide material, a silicon nitride material or a silicon carbon nitride material.

The substrate 601 may include a portion an NMOS device region 603 and a portion in PMOS device region 605 as needed, and each of the semiconductor fins 602 may be sequentially and alternatively formed in the NMOS device region 603 and the PMOS device region 605 in the substrate 601.

In one or more embodiments, if the semiconductor device structure 600 is a FinFET, the semiconductor fins 602 are formed protruding above the top surfaces of the STI structures 604 with the epitaxial structures growing on the semiconductor fins 602. In one or more other embodiments, if the semiconductor device structure 600 is a GAA FET, the channel regions of the first semiconductor region 402 and/or the second semiconductor region 404, i.e., the second semiconductor layer(s) 412, that lie in a plane in front of or behind the illustrated cross-section in the y-direction are illustrated in phantom.

Referring to FIG. 6A, at operation 520 an epitaxial deposition process is performed. The epitaxial deposition process may be similar to the epitaxial deposition process described during operation 340. The epitaxial deposition process of operation 520 forms a doped silicon-containing layer on the exposed surfaces of the substrate 610. In the embodiment depicted in FIG. 6A, the doped silicon-containing layers form epitaxial structures 632, 634 having a perimeter 650a-b. The epitaxial structures 632, 634 can be part of the source/drain feature 450. In one or more embodiments, the perimeter 650a-b of the epitaxial structures 632, 634 has a diamond shape or a partial diamond shape. The epitaxial structure 632, 634 may be formed as part of the semiconductor fins 602 (if present). The epitaxial structures 632, 634 may form doped source and drain regions.

The shape of the epitaxial structures 632, 634 is formed due to different growth rates on different crystal surface planes or orientations from the underlying materials. For example, the growth rate on a silicon surface with <111> orientation may be slower than other planes, such as <110> or <100> orientations. As such, as different growth rates may occur at different surfaces, the epitaxial structures 632, 634 formed thereon may have a wider horizontal width at a lateral portion than a vertical length formed on a top portion of the epitaxial structures 632, 634. As the deposition process proceeds, the lateral portion of the epitaxial structures 632, 634 may be undesirably merged, forming an overlapping portion. Undesired merging between the epitaxial structures 632, 634 often results in increased parasitic capacitance, resulting in poor electrical performance and potentially device failure. As depicted in FIG. 6A, the epitaxial structures 632, 634 are separated by a small distance “D1”.

Referring to FIG. 6B, at operation 530, a cyclic pulse etching process is performed to shape the doped silicon-containing material. The cyclic etching process of operation 530 can be performed similarly to the cyclic pulse etching process of operation 350. However, it should be noted that in some embodiments, in order to achieve a specific y-cut profile, or a specific x-cut profile, the process conditions are adjusted to accommodate the profile need of both the x-cut and y-cut. For example, in some embodiments, the profile in either the x-cut or the y-cut is sacrificed in order to achieve a desired profile in the other cut. The doped silicon-containing material, for example, the epitaxial structures 632, 634, are shaped by selectively removing portions of the doped silicon-containing material. As shown in FIG. 6B, the epitaxial structures 632, 634 are shaped by selectively removing portions of the epitaxial structures 632, 634. The cyclic pulse etching process of operation 530 increases the distance between the epitaxial structures 632, 634. As a result of performing the cyclic pulsed etching process of operation 530 the lateral dimension “L1” of the epitaxial structures 632, 634 shown in FIG. 6A is reduced significantly while the height of the epitaxial structures 632, 634 is substantially unchanged. As shown in FIG. 6B, the lateral dimension “L2” is much smaller than the lateral dimension “L1” shown in FIG. 6A, while the height “H2” shown in FIG. 6B is substantially unchanged or greater than the height “H1” shown in FIG. 6A. Not to be bound by theory but it is believed that lateral portions of the epitaxial structures 632, 634 can be gently etched away by the incoming etchant gas via a “gas supply depletion” mechanism to preferentially etch epitaxial material along sidewall surfaces 642, 644. Thus, the cyclic pulse etching process can be used to prevent merging and for critical dimension control of epitaxial structures.

At operation 540, the epitaxial deposition process of operation 520 and the cyclic pulse etching process of operation 530 may be repeated until the epitaxial structures 632, 634 achieve a targeted height without merging.

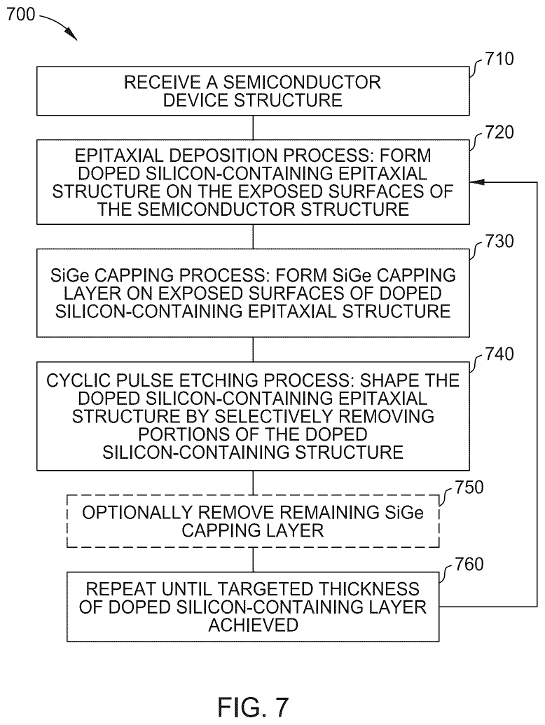

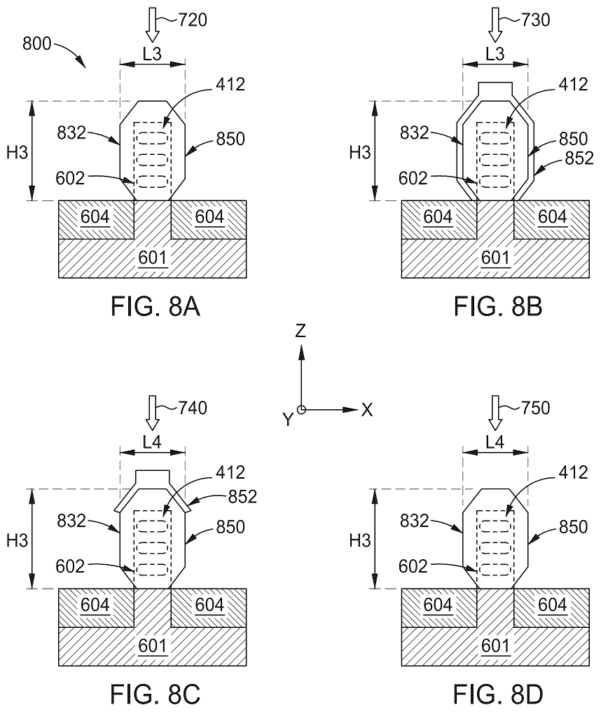

FIG. 7 illustrates an exemplary flow chart of another method 700 in accordance with one or more embodiments of the present disclosure. FIGS. 8A-8D illustrate side views of various stages of manufacturing a semiconductor device structure according to the method 700 of FIG. 7 in accordance with one or more embodiments of the present disclosure. Although FIGS. 8A-8D are described in relation to the method 700, it will be appreciated that the semiconductor device structure 800 disclosed in FIGS. 8A-8D are not limited to the method 700 but instead may stand alone as structures independent of the method 700. Similarly, although the method 700 is described in relation to FIGS. 8A-8D, it will be appreciated that the method 700 is not limited to the semiconductor device structure 800 disclosed in FIGS. 8A-8D but instead may stand alone independent of the semiconductor device structure 800 disclosed in FIGS. 8A-8D. FIGS. 8A-8D illustrate only partial schematic views of the semiconductor device structure, and the semiconductor device structure 800 may contain any number of additional layers and/or additional materials common to semiconductor device structures, which are not shown for the sake of brevity. It should also be noted that although the method 700 illustrated in FIG. 7 is described sequentially, other process sequences that include one or more operations that have been omitted and/or added, and/or have been rearranged in another desirable order, fall within the scope of the embodiments of the disclosure provided herein. The method 700 may be performed using any suitable system, for example, the multi-chamber processing system 100. In one or more embodiments, the method 700 or parts of the method 700 are performed in the processing chamber 200.

The method 700 includes another embodiment in which the cyclic pulse etching process described in operation 350 is used for shaping epitaxial features. The cyclic pulse etching process of the method 700 is used for shaping epitaxial features, for example, epitaxial features formed in a FinFET or GAA FET structure. In one or more embodiments, FIGS. 8A-8D illustrate side views taken along the x-direction or x-cut of the semiconductor device structure 400. In other embodiments, FIGS. 6A-6B illustrate side views of a GAA FET structure. The method 700 may be performed simultaneously with the method 300. For example, in one or more embodiments, the cyclic pulse etching of operation 350 not only removes epitaxial material from the epitaxial features in the y-cut shown in FIG. 4A-4D but also shapes the epitaxial features in the x-cut shown in FIGS. 8A-8D. In one or more other embodiments, the method 300 and the method 700 are performed sequentially. For example, after the targeted thickness of the source/drain feature 450 is achieved, the method 700 is performed to shape the epitaxial features along the x-cut. The method 700 includes forming a capping layer on the perimeter of the epitaxial structure. The capping layer enables preferential etching along the sidewall surfaces of the epitaxial structure while the capping layer protects the top of the epitaxial structure. Thus, the size of the epitaxial structure can be laterally reduced to prevent merging without affecting the height of the epitaxial structure.

Referring to FIG. 8A, at operation 710, a semiconductor device structure 800 is received. The semiconductor device structure 800 can be a FinFET or GAA FET structure. The semiconductor device structure 800 can include the substrate 601. The semiconductor device structure 800 can further include STI structures 604. If the semiconductor device structure 800 is a FinFET structure, the substrate 601 can include a plurality of semiconductor fins 602, shown in phantom, formed thereon isolated by the STI structures 604. The STI structures 604 may be formed by an insulating material, such as a silicon oxide material, a silicon nitride material or a silicon carbon nitride material.

In one or more embodiments, if the semiconductor device structure 800 is a FinFET, the semiconductor fins 602 are formed protruding above the top surfaces of the shallow trench isolation (STI) structures 604 with the epitaxial structures growing on the semiconductor fins 602. In one or more other embodiments, if the semiconductor device structure 800 is a GAA FET, the channel regions of the first semiconductor region 402 and/or the second semiconductor region 404, i.e., the second semiconductor layer(s) 412, that lie in a plane in front of or behind the illustrated cross-section in the y-direction are illustrated in phantom.

Referring to FIG. 8A, at operation 720, an epitaxial deposition process is performed. The epitaxial deposition process may be similar to the epitaxial deposition process described during operation 340. The epitaxial deposition process of operation 520 forms a doped silicon-containing material on the exposed surfaces of the substrate 610. In the embodiment depicted in FIG. 8A, the doped silicon-containing material forms an epitaxial structure 832 having a perimeter 850. The epitaxial structure 832 can be part of the source/drain feature 450. In one or more embodiments, the perimeter 850 of the epitaxial structure 832 has a diamond shape or a partial diamond shape. The epitaxial structure 832 may be formed as part of the semiconductor fins 602 (if present). The epitaxial structure 832 may form doped source and drain regions. The shape of the epitaxial structure 832 is formed due to different growth rates on different crystal surface planes or orientations from the underlying materials. The epitaxial structure 832 has a lateral width “L3”and a vertical height “H3”.

Referring to FIG. 8B, at operation 730, a SiGe capping process is performed. The SiGe capping process includes forming a SiGe capping layer 852 on the exposed surfaces along the perimeter 850 of the epitaxial structure 832. The SiGe capping layer 852 may be thicker along the top surfaces of the epitaxial structure 832 than on the sidewalls of the epitaxial structure 832. The SiGe capping layer 852 can be formed any suitable process. In one or more embodiments, the SiGe capping layer 852 is formed by an epitaxial deposition process. The SiGe capping process of operation 730 can be performed similarly to the epitaxial deposition process of operation 530. In one or more embodiments, the SiGe capping process includes flowing SiH4 and GeH4 and/or GeCl4 to deposit the SiGe capping layer 852.

In one or more embodiments, during operation 730, the SiGe capping layer 852 is formed by a selective epitaxial deposition process. The selective epitaxial deposition process includes co-flowing an etchant gas with the deposition gases. The etchant gas can be selected from HCl, Cl2, HBr, PCl3, AsCl3, GeCl4, or a combination thereof.

In one or more embodiments, during operation 730, the SiGe capping layer 852 is formed by a non-selective epitaxial deposition process. The non-selective epitaxial deposition process includes flowing the deposition gases, for example, SiH4 without co-flowing an etchant gas.

The deposition gas may be provided with a carrier gas. The carrier gas may have a flow rate in a range from about 1 SLM to about 100 SLM, or in a range from about 2 SLM to about 30 SLM, or in a range from about 2 SLM to about 5 SLM. Suitable carrier gases include nitrogen (N2), hydrogen (H2), argon, helium, or combinations thereof. The carrier gas may be selected based on the reactants used and/or the process temperature during the soak process.

In one or more embodiments, the epitaxial deposition process of operation 730 includes flowing silane, germane, hydrogen, and optionally HCl. In one or more embodiments, the process conditions of the SiGe growth process of operation 730 is selected for higher SiGe growth ratio of (100)/(110). In one or more embodiments, a ratio of the growth rate of SiGe on (100) surfaces to the growth rate of SiGe on (110) surfaces is in a range from 2 to 7 or in a range from 3 to 6, or in a range from 3 to 5.

During operation 730, a first pressure of an environment in a processing chamber in which the epitaxial growth is performed can be maintained in a range from about 1 Torr to about to about 100 Torr, or from about 2 Torr to about 50 Torr, or from about 5 Torr to about 50 Torr, or from about 5 Torr to about 10 Torr. A first temperature of the substrate 406 during the epitaxial growth can be maintained at about 750° C. or less, or at about 700° C. or less, or at about 650° C. or less, or at about 600° C. or less, and more particularly in a range from about 400° C. to about 750° C., or from about 500° C. to about 700° C., or from about 450° C. to about 650° C., or from about 500° C. to about 550° C.

Referring to FIG. 8C, at operation 740, a cyclic pulse etching process is performed. The cyclic pulse etching process shapes the silicon-containing epitaxial structures. The cyclic etching process of operation 740 can be performed similarly to the cyclic pulse etching process of operation 350. The doped silicon-containing material, for example, the epitaxial structure 832, is shaped by selectively removing portions of the doped silicon-containing material. As shown in FIG. 8C, the epitaxial structures 832, is shaped by selectively removing portions of the epitaxial structure 832. As a result of performing the cyclic pulsed etching process of operation 740 the lateral dimension “L3” of the epitaxial structure 832 shown in FIG. 8B is reduced significantly while the height of the epitaxial structure 832 is substantially unchanged do to the thicker SiGe capping layer 852 on the top surfaces of the epitaxial structure 832. As shown in FIG. 8C, the lateral dimension “L4” is smaller than the lateral dimension “L3” shown in FIG. 8B, while the height “H3” shown in FIG. 8C is substantially unchanged relative to the height “H3” shown in FIG. 8B. Not to be bound by theory but it is believed that lateral portions of the epitaxial structure 832 can be gently etched away by the incoming etchant gas via a “gas supply depletion” mechanism to preferentially etch the SiGe capping layer 852 and epitaxial material along sidewall surfaces of the epitaxial structure 832 while the epitaxial material along the top surfaces of the epitaxial structure 832 remains protected by the SiGe capping layer. Thus, the cyclic pulse etching process can be used to prevent merging and for critical dimension control of adjacent epitaxial structures.

Referring to FIG. 8D, optionally at operation 750, the remaining SiGe capping layer 852 is removed. In one or more embodiments, an additional etching process is performed at operation 750 to remove the remaining SiGe capping layer 852. Any suitable etching process can be used to remove the remaining SiGe capping layer 852. In one or more embodiments, the remaining SiGe capping layer 852 is removed by performing additional cycles of the cyclic etching process of operation 740.

At operation 760, the epitaxial deposition process of operation 720, the SiGe capping process of operation 730, the cyclic pulse etching process of operation 740, and the optional SiGe capping layer removal process may be repeated until the epitaxial structure 832 achieve a targeted height without merging with adjacent epitaxial structures.

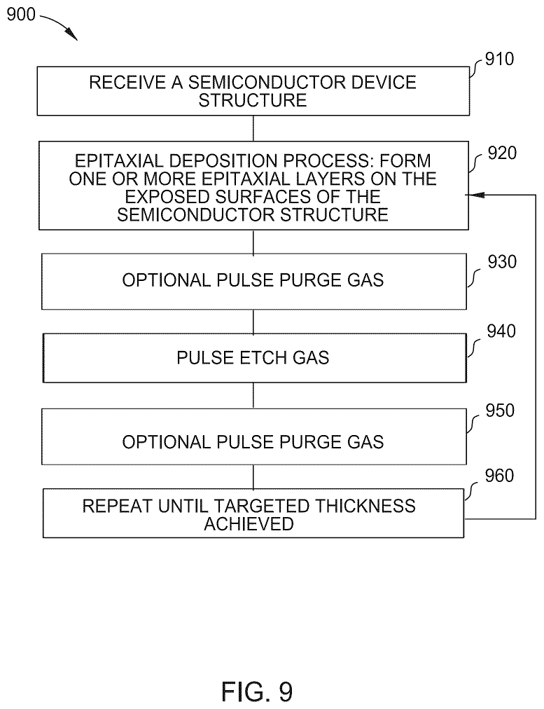

FIG. 9 illustrates an exemplary flow chart of yet another method 900 in accordance with one or more embodiments of the present disclosure. The method 900 can be performed using any suitable system, for example, the multi-chamber processing system 100. The method 900 includes a cyclic pulse deposition/pulse etch process. In one or more embodiments, one cycle of the cyclic pulse deposition/pulse etch process includes a pulse of deposition gas followed by of pulse of etching gas. In one or more embodiments, the method 900 or parts of the method 900 are performed in the processing chamber 200. For example, the pulse deposition process and pulse etch process are performed in-situ in the same chamber, such as the processing chamber 200 shown in FIG. 2. The cyclic pulse deposition/pulse etch process can be repeated for a number of cycles to deposit an epitaxial material, for example, a silicon-containing epitaxial material. The cyclic pulse deposition/pulse etch process can further include a pulse of purge gas between the pulse of deposition gas and the pulse of etching gas. For example, one cycle of the cyclic pulse deposition/pulse etch process can include a pulse of deposition gas followed by a pulse of purge gas followed by a pulse of etching gas. In some embodiments which exclude the purge gas, the etch gas and deposition gas can mix in a dynamic way, for example, the gas mixture can be rich in deposition gas or rich in etching gas. In some embodiments which include the purge gas, the purge gas reduces interaction of the deposition gas and the etching gas in the chamber.

The cyclic pulse deposition/pulse etch process is applicable to both NMOS and PMOS structures. As an example, the methods can form film as part of n-type epitaxial deposition such as to form silicon phosphorus (Si:P) for NMOS (N-channel MOSFET) transistors. As an example, the methods can form film as part of p-type epitaxial deposition such as to form silicon-germanium-boron (SiGe:B) for PMOS (P-channel MOSFET) transistors.

In one or more embodiments, the cyclic pulse deposition/pulse etch process includes a pulse of deposition gas followed by a pulse of etch gas until the GAA or FinFET recess is filled to a targeted thickness. The cyclic pulse deposition/pulse etch process described can be performed using typical NMOS and PMOS process conditions. The temperature during the cyclic pulse etching process could be either the same or different from the epitaxial deposition temperature. Pulse etch pressure/purge pressure can be in a range from about 5 torr to about 600 torr. The pulse etchant gases can be provided in a carrier gas, for example, H2 or N2, at a flow rate in a range from about 500 sccm to 30 SLM. The carrier gas can be used as the purge gas during the optional purge operation. First etchant gases include but are not limited to (1) HCl, Cl2, HBr, combinations thereof or other suitable etchants compatible in the chamber design. Second etchant gases include but are not limited to (2) PCl3, AsCl3, GeCl4, or combinations thereof. Deposition gases can include silicon-containing gases, germanium-containing gases, or both silicon-containing gases and germanium-containing gases, for example, (3) SiH4, SiH2Cl2, Si2H6, Si3H8, Si4H10, GeH4, or Ge2H6; and (4) 1, 2, 3 types of gases can be injected (in the pulse mode) at the same time or in any sequential order. In one or more embodiments, sequential order includes injecting deposition gas and etchant gases at different time slots in a pulsed way similar to an atomic layer deposition process. The pulsed etchant and deposition gases can be laterally injected into the processing volume and purged out of the processing volume on the exhaust side. The pulsed etchant and deposition gases can be vertically injected into the processing volume through the XT plate with (mesh holes), for example, a showerhead.

At operation 910, a semiconductor device structure is received. The semiconductor device structure can be positioned on The semiconductor device structure can be a FinFET or GAA FET structure. The semiconductor device structure can be any suitable semiconductor device structure. The semiconductor device structure can be or include the include the semiconductor device structure 400, the semiconductor device structure 600, or the semiconductor device structure 800. In one or more embodiments, the semiconductor device structure is positioned on a substrate support, for example, the substrate support 260, in the processing volume of the chamber 200.

At operation 920, an epitaxial deposition process is performed. The cyclic pulse deposition/pulse etch process includes the epitaxial deposition process of operation 920. The epitaxial deposition process of operation 920 includes pulsing a deposition gas for a first time period. Deposition gases can include silicon-containing gases, germanium-containing gases, or both silicon-containing gases and germanium-containing gases. The epitaxial deposition process includes forming one or more epitaxial layers on the exposed surfaces of the semiconductor structure. The epitaxial deposition process of operation 920 may be similar to the epitaxial deposition process described during operation 340. In one or more embodiments of the epitaxial deposition process of operation 920 includes depositing a single epitaxial layer of semiconductor material. The epitaxial layer of semiconductor material can be or include a silicon-containing material, a germanium-containing material, or a silicon and germanium containing material. The semiconductor material can be doped, for example, the semiconductor material can be p-type doped or n-type doped as described herein.

At operation 930, an optional pulse of purge gas is performed. In one or more embodiments, the cyclic pulse deposition/pulse etch process includes the pulse of purge gas at operation 930. The pulse of purge gas includes flowing purge gas for a second time period. In one or more embodiments, the purge gas of operation 930 flows at a higher flow rate than the etch gas of operation 940. In one or more embodiments, the etch gas is flowed for an etch time and the purge gas is flowed for a purge time that is greater than the etch time.

At operation 940, a pulse of etch gas is performed. In one or more embodiments, t he cyclic pulse deposition/pulse etch process includes the pulse of etch gas at operation 940. The etch process of operation 940 includes pulsing an etchant gas for a third time period. The pulse of etchant gas can include the first etchant gas, the second etchant gas, or a combination of the first etchant gas and the second etchant gas. Deposition gases can include silicon-containing gases, germanium-containing gases, or both silicon-containing gases and germanium-containing gases. In one or more embodiments, the etch gas flows at a flow rate of at least 500 sccm, such as about 600 sccm. The pulse of etch gas can selectively remove and/or shape portions of the previously deposited epitaxial material.

At operation 950, an optional second pulse of purge gas is performed. In one or more embodiments, the cyclic pulse deposition/pulse etch process includes the second pulse of purge gas at operation 950. The second pulse of purge gas includes flowing purge gas for a fourth time period. In one or more embodiments, the purge gas of operation flows at a higher flow rate than the etch gas of operation 940. In one or more embodiments, the etch gas is flowed for an etch time and the purge gas is flowed for a purge time that is greater than the etch time.

In one or more embodiments, the first time period, the second time period, the third time period, and the fourth time period are each independently five seconds or less, or four seconds or less, or three seconds or less, or two seconds or less, or one second or less. In one or more embodiments, the first time period, the second time period, the third time period, and the fourth time period are each independently in a range from about ten milliseconds to five seconds, or in a range from about one second to about five seconds, or in a range from one second to about 3 seconds.

At operation 960, the cyclic pulse deposition/pulse etch process epitaxial can be repeated for a number of cycles until the epitaxial layer achieved a targeted thickness.

In one example, the cyclic pulse deposition/pulse etch process includes pulsing a deposition gas, for example, a silicon-containing gas, a germanium-containing gas, or both a silicon containing gas and a germanium-containing gas for a first time period (e.g., one second) followed by pulsing an etchant gas, for example, the first etchant gas for a second time period (e.g., one second), and repeating the pulse of deposition gas and pulse of the first etchant gas for multiple cycles.

In another example, the cyclic pulse deposition/pulse etch process includes pulsing a deposition gas, for example, a silicon-containing gas, a germanium-containing gas, or both a silicon containing gas and a germanium-containing gas for a first time period (e.g., one second) followed by pulsing an etchant gas, for example, the second etchant gas for a second time period (e.g., one second), and repeating the pulse of deposition gas and pulse of the second etchant gas for multiple cycles.

In yet another example, the cyclic pulse deposition/pulse etch process includes pulsing a deposition gas, for example, a silicon-containing gas, a germanium-containing gas, or both a silicon containing gas and a germanium-containing gas for a first time period (e.g., one second) followed by pulsing an etchant gas, for example, a combination of the first etchant gas and the second etchant gas for a second time period (e.g., one second), and repeating the pulse of deposition gas and pulse of the mixture of the first etchant gas and the second etchant gas for multiple cycles.

The previously described embodiments of the present disclosure have many advantages. After deposition of a targeted Epi film thickness, etchant gas can be injected into an epitaxial chamber for a short time period (˜seconds) before purging the etchant gas out of chamber. In this pulse mode, etchant gas molecules do not have sufficient time to reach the bottom of the trench in the GAA or FinFET by collision. Accordingly, the top portion of the GAA or FinFET recess can be gently etched away by the incoming etchant gas. It can be imagined as “gas supply depletion” in a transit from top structure to bottom structure to preferentially etch films on the sidewall and top portion of the GAA or FinFET. Some embodiments of the present disclosure provide epitaxial growth shape/defectivity control: (1) bottom-up growth (instead of strong sidewall growth); (2) thinning of the epitaxial film on the top silicon pair by a cyclic pulse purge/pulse HCl etch to suppress top-pair “pinch-off” (void issue), and (3) shaping of epitaxial structures to prevent merging of adjacent epitaxial structures. However, the present disclosure does not necessitate that all the advantageous features and the advantages need to be incorporated into every embodiment of the present disclosure.

In the Summary and in the Detailed Description, and the Claims, and in the accompanying drawings, reference is made to particular features (including method operations) of the present disclosure. It is to be understood that the disclosure in this specification includes all possible combinations of such particular features. For example, where a particular feature is disclosed in the context of a particular aspect, implementation, implementation, or example of the present disclosure, or a particular claim, that feature can also be used, to the extent possible in combination with and/or in the context of other particular aspects and embodiments of the present disclosure, and in the present disclosure generally.

Embodiments and all of the functional operations described in this specification can be implemented in digital electronic circuitry, or in computer software, firmware, or hardware, including the structural means disclosed in this specification and structural equivalents thereof, or in combinations of them. Embodiments described herein can be implemented as one or more non-transitory computer program products, i.e., one or more computer programs tangibly embodied in a machine readable storage device, for execution by, or to control the operation of, data processing apparatus, e.g., a programmable processor, a computer, or multiple processors or computers.

The processes and logic flows described in this specification can be performed by one or more programmable processors executing one or more computer programs to perform functions by operating on input data and generating output. The processes and logic flows can also be performed by, and apparatus can also be implemented as, special purpose logic circuitry, e.g., an FPGA (field programmable gate array) or an ASIC (application specific integrated circuit).

The term “data processing apparatus” encompasses all apparatus, devices, and machines for processing data, including by way of example a programmable processor, a computer, or multiple processors or computers. The apparatus can include, in addition to hardware, code that creates an execution environment for the computer program in question, e.g., code that constitutes processor firmware, a protocol stack, a database management system, an operating system, or a combination of one or more of them. Processors suitable for the execution of a computer program include, by way of example, both general and special purpose microprocessors, and any one or more processors of any kind of digital computer.

Computer readable media suitable for storing computer program instructions and data include all forms of nonvolatile memory, media and memory devices, including by way of example semiconductor memory devices, e.g., EPROM, EEPROM, and flash memory devices; magnetic disks, e.g., internal hard disks or removable disks; magneto optical disks; and CD ROM and DVD-ROM disks. The processor and the memory can be supplemented by, or incorporated in, special purpose logic circuitry.

The term “comprises,” and grammatical equivalents thereof are used herein to mean that other components, ingredients, operations, are optionally present. For example, an article “comprising” (or “which comprises”) components A, B, and C can consist of (i.e., contain only) components A, B, and C, or can contain not only components A, B, and C but also one or more other components. In addition, whenever a composition, an element or a group of elements is preceded with the transitional phrase “comprising” or grammatical equivalents thereof, it is understood that it is contemplated that the same composition or group of elements may be preceded with transitional phrases “consisting essentially of,” “consisting of,” “selected from the group of consisting of,” or “is” preceding the recitation of the composition, element, or elements and vice versa.

Where reference is made herein to a method comprising two or more defined operations, the defined operations can be carried out in any order or simultaneously (except where the context excludes that possibility), and the method can include one or more other operations which are carried out before any of the defined operations, between two of the defined operations, or after all of the defined operations (except where the context excludes that possibility).

When introducing elements of the present disclosure or exemplary aspects or implementation(s) thereof, the articles “a,” “an,” “the” and “said” are intended to mean that there are one or more of the elements.

The terms “comprising,” “including” and “having” are intended to be inclusive and mean that there may be additional elements other than the listed elements.

While the foregoing is directed to embodiments of the present disclosure, other and further embodiments of the disclosure may be devised without departing from the basic scope thereof, and the scope thereof is determined by the claims that follow.

1. A method of forming a semiconductor device, comprising:
performing an epitaxial deposition process, the epitaxial deposition process comprising epitaxially growing a doped silicon-containing material on a pair of opposing sidewall surfaces and a bottom surface to a targeted thickness, the pair of opposing sidewall surfaces and the bottom surface defining a source/drain cavity; and
performing a cyclic pulse etching process for a number of cycles to selectively remove portions of the doped silicon-containing material to form a modified doped silicon-containing material, the modified doped silicon-containing material having a U-shaped profile.

2. The method of claim 1, further comprising:
repeating the epitaxial deposition process and the cyclic pulse etching process for a number of cycles to fill the source/drain cavity to a targeted thickness with the doped silicon-containing material.

3. The method of claim 1, wherein the cyclic pulse etching process removes an upper portion of the doped silicon-containing material coating an upper portion of the sidewall surfaces at greater rate than a lower portion of the doped silicon-containing material coating a lower portion of the sidewall surfaces and the bottom surface.

4. The method of claim 1, wherein the cyclic pulse etching process further comprises pulsing a silicon deposition gas, a germanium deposition gas, or both a silicon deposition gas and a germanium deposition gas.

5. The method of claim 1, wherein the cyclic pulse etching process comprises pulsing an etchant gas selected from HCl, Cl2, HBr, PCl3, AsCl3, GeCl4, or a combination thereof.

6. The method of claim 5, wherein the cyclic pulse etching process further comprises flowing a carrier gas selected from hydrogen, nitrogen, or a combination thereof.

7. The method of claim 6, wherein the cyclic pulse etching process further comprises pulsing a silicon deposition gas, a germanium deposition gas, or both a silicon deposition gas and a germanium deposition gas.

8. A method of forming a semiconductor device, comprising:
performing an epitaxial deposition process in a processing volume of a processing chamber, the epitaxial deposition process comprising epitaxially growing a doped silicon-containing material on a pair of opposing sidewall surfaces and a bottom surface to a targeted thickness, the pair of opposing sidewall surfaces and the bottom surface defining a source/drain cavity,
performing a cyclic pulse etching process subsequent to the epitaxial deposition process, the cyclic pulse etching process, comprising:
pulsing a process gas comprising an etchant gas into the processing volume for a first period of time;
pulsing a purge gas into the processing volume for a second period of time; and
repeating the cyclic pulse etching process for a number of cycles to selectively remove a portion of the doped silicon-containing material from the source/drain cavity.

9. The method of claim 8, further comprising:
repeating the epitaxial deposition process and the cyclic pulse etching process for a number of cycles to fill the source/drain cavity to a targeted thickness with the doped silicon-containing material.

10. The method of claim 8, wherein the first period of time is less than the second period of time.

11. The method of claim 8, wherein the second period of time is five seconds or less.

12. The method of claim 8, wherein the etchant gas and the purge gas are laterally injected into the processing volume.

13. The method of claim 8, wherein the etchant gas and the purge gas are vertically injected into the processing volume.

14. The method of claim 8, wherein the etchant gas is HCl, Cl2, HBr, PCl3, AsCl3, GeCl4, or a combination thereof.

15. The method of claim 14, wherein the process gas further comprises a silicon deposition gas, a germanium deposition gas, or both a silicon deposition gas and a germanium deposition gas.

16. The method of claim 8, wherein the cyclic etching process further comprises pulsing a silicon deposition gas, a germanium deposition gas, or both a silicon deposition gas and a germanium deposition gas.

17. A non-transitory computer readable medium comprising instructions that, when executed, cause a plurality of operations to be conducted, the plurality of operations, comprising:
performing an epitaxial deposition process in a processing volume of a processing chamber, the epitaxial deposition process comprising epitaxially growing a doped silicon-containing material on a pair of opposing sidewall surfaces and a bottom surface to a targeted thickness, the pair of opposing sidewall surfaces and the bottom surface defining a source/drain cavity,
performing a cyclic pulse etching process subsequent to the epitaxial deposition process, the cyclic pulse etching process, comprising:
pulsing a process gas comprising an etchant gas into the processing volume for a first period of time;
pulsing a purge gas into the processing volume for a second period of time; and
repeating the cyclic pulse etching process for a number of cycles to selectively remove a portion of the doped silicon-containing material.

18. The non-transitory computer readable medium of claim 17, wherein the first period of time is less than the second period of time.

19. The non-transitory computer readable medium of claim 17, wherein the etchant gas is HCl, Cl2, HBr, PCl3, AsCl3, GeCl4, or a combination thereof.

20. The non-transitory computer readable medium of claim 17, wherein the process gas further comprises a silicon deposition gas, a germanium deposition gas, or both a silicon deposition gas and a germanium deposition gas.
